(19) United States
(12) Patent Application Publication
(10) Pub. No.: US 2023/0171994 A1
(43) Pub. Date: Jun. 1, 2023

(54) LIGHT EMITTING DISPLAY DEVICE

(71) Applicant: Samsung Display Co., Ltd., Yongin-Si (KR)

(72) Inventors: Wang Woo LEE, Osan-si (KR); Sung Ho KIM, Suwon-si (KR); Seok Je SEONG, Seongnam-si (KR); Jin Sung AN, Gwacheon-si (KR); Min Woo WOO, Seoul (KR); Seung Hyun LEE, Asan-si (KR); Ji Seon LEE, Hwaseong-si (KR); Yoon-Jong CHO, Seongnam-si (KR)

(21) Appl. No.: 17/879,051

(22) Filed: Aug. 2, 2022

(30) Foreign Application Priority Data
Nov. 26, 2021 (KR) 10-2021-0165853

(51) Int. Cl. H01L 51/52; H01L 27/32

(52) U.S. Cl. CPC H01L 51/5284; H01L 27/3234; H01L 27/3276

(57) ABSTRACT

The present disclosure relates to a light emitting display device that includes a transparent display area including a light transmission area and a normal display area, wherein the transparent display area includes: an anode including an opening; a first light blocking part filling the opening; and a second light blocking part positioned along an exterior side of the anode. A height of a highest part of the first light blocking part is different than a height of a highest part of the second light blocking part.

### CROSS-REFERENCE TO RELATED APPLICATION

This application claims priority to and the benefit of Korean Patent Application No. 10-2021-0165853 filed in the Korean Intellectual Property Office on Nov. 26, 2021, the entire contents of which are incorporated herein by reference.

### BACKGROUND

### 1. Field

The present disclosure relates to a light emitting display device, and more particularly, to a light emitting display device that positions an optical element such as a camera on a rear surface of a display area.

### 2. Description of the Related Art

A display device is a device for displaying an image, and includes a liquid crystal display (LCD), an organic light emitting diode (OLED) display, and the like. The display device is used in various electronic devices such as a mobile phone, a navigation device, a digital camera, an electronic book, a portable game machine, and various terminals.

The display device such as the organic light emitting display device may have a structure in which the display device can be bent or folded by using a flexible substrate.

In addition, in small electronic devices such as portable phones, optical elements such as cameras and optical sensors are formed in a bezel area, which is a periphery of the display area. However as the size of the peripheral area of the display area is gradually reduced while the size of the screen to be displayed is increased, a technology that allows the cameras or the optical sensors to be positioned on the back of the display area is being developed.

The above information disclosed in this Background section is only for enhancement of understanding of the background of the described technology, and therefore it may contain information that does not form the prior art that is already known in this country to a person of ordinary skill in the art.

### SUMMARY

Embodiments are for appropriately removing residual moisture from an organic layer positioned on a front surface of an optical element to prevent a step difference from occurring in the organic layer.

A light emitting display device according to an embodiment includes: a transparent display area including a light transmission area and a normal display area, wherein the transparent display area includes an anode including an opening; a first light blocking part filling the opening; and a second light blocking part positioned along an exterior side of the anode. A height of a highest part of the first light blocking part is different than a height of a highest part of the second light blocking part.

The first light blocking part and the second light blocking part may include a light blocking material or a negative organic material having a black color.

The height of the highest part of the first light blocking part may be higher than the height of the highest part of the second light blocking part.

The first light blocking part is divided into a periphery part and a center part, and a height of the center part may be higher than a height of the periphery part.

A partition wall and a spacer may be positioned in the normal display area, and the partition wall and the spacer may include a same material as the first light blocking part and the second light blocking part.

The height of the highest part of the first light blocking part may be lower than the height of the highest part of the second light blocking part.

The partition wall and the spacer may be positioned in the normal display area, and the partition wall and the spacer may comprise a same material as the first light blocking part and the second light blocking part.

Among an entire area surrounded by the exterior side of the anode for the transparent display area, an area occupied by the opening may be 5% or more and 20% or less.

At least one of a plurality of insulating layers positioned in the normal display area and transparent connection wiring connected to the anode for the transparent display area may be positioned in the light transmission area.

The transparent connection wiring may be connected to the anode for the transparent display area at a position where the first light blocking part and the second light blocking part, and the anode for the transparent display area overlap on a plane.

The transparent connection wiring may be connected to the anode for the transparent display area at a position where the first light blocking part and the second light blocking part overlap, and the anode for the transparent display area does not overlap on a plane.

A part where the transparent connection wiring and the anode for the transparent display area may be connected overlaps the first light blocking part or the second light blocking part on a plane.

A light emitting display device according to an embodiment includes: a normal display area where a pixel circuit unit for a normal display area and a light-emitting element for the normal display area connected to the pixel circuit unit for the normal display area are positioned; a transparent display area where a light-emitting element for the light transmission area and the transparent display area is positioned; and an intermediate display area where a pixel circuit unit for the intermediate display area, a light-emitting element for the intermediate display area connected to the pixel circuit unit for the intermediate display area, and a pixel circuit unit for the transparent display area connected to the light-emitting element for the transparent display area are positioned. The light-emitting element for the transparent display area includes an anode for the transparent display area, the anode for the transparent display area has an opening. The transparent display area further includes a first light blocking part filling the opening; and a second light blocking part positioned along the exterior side of the anode. A height of the highest part of the first light blocking part is different than a height of a highest part of the second light blocking part.

The height of the highest part of the first light blocking part may be higher than the height of the highest part of the second light blocking part.

The first light blocking part may be divided into a periphery part and a center part, and a height of the center part may be higher than a height of the periphery part.

A partition wall and a spacer may be positioned in the normal display area, and the partition wall and the spacer include a same material as the first light blocking part and the second light blocking part.

The height of the highest part of the first light blocking part may be lower than the height of the highest part of the second light blocking part.

A partition wall and a spacer may be positioned in the normal display area, and the partition wall and the spacer may include a same material as the first light blocking part and the second light blocking part.

An area occupied by the opening may be 5% or more and 20% or less among an entire area surrounded by the exterior side of the anode for the transparent display area.

In the light transmission area, at least one of a plurality of insulating layers positioned in the normal display area and transparent connection wiring connected to the anode for the transparent display area may be positioned.

According to embodiments, by forming the opening as a gas discharge passage in the anode positioned on the upper surface of the organic layer positioned on the front surface of the optical element, it is possible to properly remove the residual moisture and prevent the step difference from occurring in the organic layer. Through this, the transmittance of the light transmission area positioned on the front surface of the optical element may also be improved.

### BRIEF DESCRIPTION OF THE DRAWINGS

FIG. 1 is a top plan view showing an enlarged partial region of a light emitting display device according to an embodiment.

FIG. 2 is a schematic enlarged view of a first display area and a second display area in a light emitting display device according to an embodiment.

FIG. 3 is a top plan view of an anode and a periphery of the anode of a second display area according to an embodiment.

FIG. 4 is a cross-sectional view taken along a line IV-IV of FIG. 3.

FIGS. 5 and 6 are cross-sectional views sequentially showing a manufacturing method of an anode of a second display area and a periphery of the anode according to an embodiment.

FIG. 7 is a cross-sectional view according to a comparative example.

FIGS. 8, 9, 10, and 11 are views of an anode and a periphery of the anode of a second display area according to an embodiment.

FIGS. 12 and 13 are views showing a connection structure of an anode of a second display area according to an embodiment.

FIG. 14 is a view showing a connection structure of an anode of a second display area according to an embodiment.

FIG. 15 is a circuit diagram of one pixel included in a light emitting display device according to an embodiment.

FIG. 16 is a view showing a cross-section of a pixel according to an embodiment of FIG. 15.

FIG. 17 is a circuit diagram of one pixel included in a light emitting display device according to an embodiment.

FIG. 18 is a view showing a cross-section of a pixel according to an embodiment of FIG. 17.

### DETAILED DESCRIPTION

The inventive concept will be described more fully hereinafter with reference to the accompanying drawings, in which embodiments are shown. As those skilled in the art would realize, the described embodiments may be modified in various different ways, all without departing from the spirit or scope of the inventive concept.

Descriptions of parts not related to the inventive concept are omitted, and like reference numerals designate like elements throughout the specification.

Further, sizes and thicknesses of constituent members shown in the accompanying drawings are arbitrarily given for better understanding and ease of description. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or above the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In addition, in the specification, when referring to “connected to”, this does not mean only that two or more constituent elements are directly connected to each other, but two or more constituent elements may be indirectly connected, physically connected, and electrically connected through other constituent elements, and it may be included that each of parts that are substantially integral are connected to each other although referred to as different names depending on the position or function.

Also, throughout the specification, when it is said that parts such as wirings, layers, films, regions, plates, and constituent elements are “extended in the first direction or second direction”, this does not mean only a straight-line shape extending straight in the corresponding direction, but it is a structure that extends overall along the first direction or the second direction, includes a structure that is bent and has a zigzag structure in a part, or includes extending while including a curved line structure.

In addition, electronic devices including display devices and display panels described in the specification, e.g., mobile phones, TV, monitors, laptop computers, etc., or display devices and electronic devices including display panels, etc. manufactured by the manufacturing method described in the specification are not excluded from the right range of this specification.

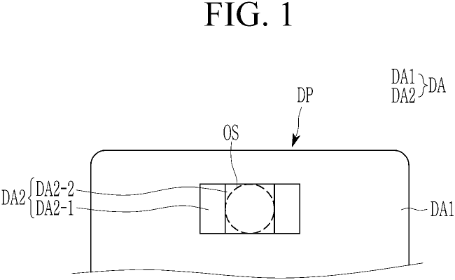

First, in the following, a display area of a light emitting display device according to an embodiment is distinguished, and a position of an optical device such as a camera or an optical sensor is described with reference to FIG. 1.

FIG. 1 is a top plan view showing an enlarged partial region of a light emitting display device according to an embodiment.

FIG. 1 shows a part of a display panel DP among a display device according to an embodiment, and is described using a display panel for a mobile phone.

A display area DA is positioned on the entire surface of the display panel DP, and the display area DA is largely divided into a first display area DA1 and a second display area DA2.

In the first display area DA1, a plurality of light-emitting elements, and a plurality of pixel circuit units generating and transmitting a light emission current to each of a plurality of light-emitting elements are formed. Here, one light-emitting element and one pixel circuit unit are referred to as a pixel PX. In the first display area DA1, one pixel circuit unit and one light-emitting element are formed on a one-to-one. The first display area DA1 is hereinafter also referred to as ‘a normal display area’.

In FIG. 1, the structure of the display panel DP under the cut line is not shown, but the first display area DA1 may be positioned under the cut line.

An optical element OS such as a camera or an optical sensor is positioned on the back side of the display panel DP, and as shown in FIG. 1, the optical element OS is positioned on the back side and is shown by a dotted line.

The second display area DA2 is positioned in front of and around the optical element OS. The second display area DA2 is divided into a second/first display area DA2-1 and a second/second display area DA2-2.

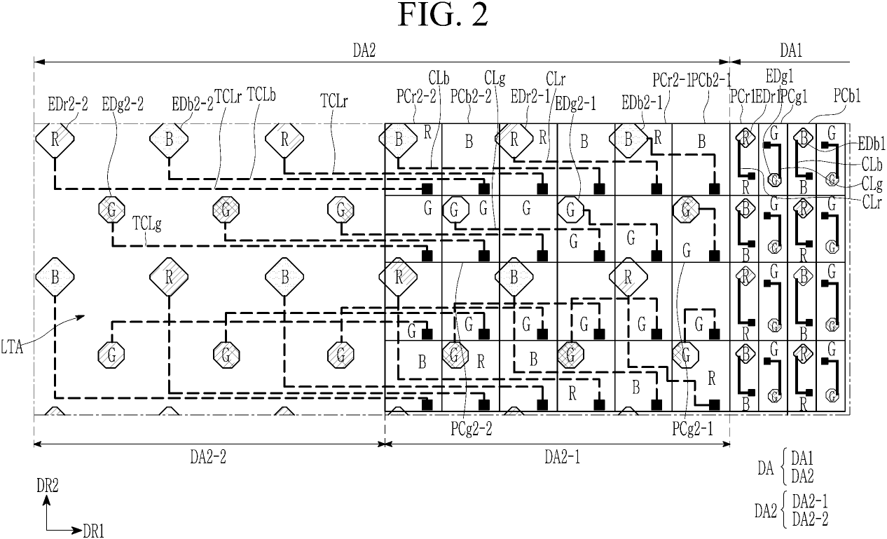

The second/second display area DA2-2 is a display area positioned on the front surface of the optical element OS, in which a plurality of light-emitting elements are formed to display an image. The pixel circuit unit that generates and transmits a light emission current to the light-emitting element is not formed in the second/second display area DA2-2, but is positioned in the adjacent second/first display area DA2-1. The pixel circuit unit positioned in the second/first display area DA2-1 and the light-emitting element positioned in the second/second display area DA2-2 may be electrically connected to each other through a transparent connection wiring. In the second/second display area DA2-2, a transparent light transmission area, e.g., refer to a light transmission area LTA in FIG. 2, is formed in the region other than the region in which a plurality of light-emitting elements are positioned. The camera or the optical sensor of the optical element OS captures or detects an object positioned in front of the display panel DP through the light transmission area. In FIG. 1, the second/second display area DA2-2 is shown as a quadrangle. However, the second/second display area DA2-2 may have a shape corresponding to the planar shape of the optical element OS, such as a circular shape, according to an embodiment. Hereinafter, the second/second display area DA2-2 is also referred to as ‘a transparent display area’.

The second/first display area DA2-1 may be positioned on one side or both sides of the second/second display area DA2-2, and is positioned between the first display area DA1 and the second/second display area DA2-2. In the second/first display area DA2-1, not only one pixel circuit unit and one light-emitting element are formed one-to-one, but also additionally, the pixel circuit unit for transmitting the light emission current to a plurality of light-emitting elements formed in the second/second display area DA2-2 is further included. Hereinafter, the second/first display area DA2-1 is also referred to as ‘an intermediate display area’.

FIG. 1 is an embodiment in which the second/first display area DA2-1 is positioned on both left and right sides of the second/second display area DA2-2. The left and right width of one second/first display area DA2-1 may have a width about half of the left and right width of the second/second display area DA2-2. In addition, the first display area DA1 is positioned in a region where the second/first display area DA2-1 is not positioned as a region adjacent to the second/second display area DA2-2. A direction in which the second/first display area DA2-1 is positioned based on the second/second display area DA2-2 may coincide with an extension direction, e.g., a first direction, of a scan line, which is described later. In addition, the transparent connection wiring formed in the second display area DA2 may extend from the second/first display area DA2-1 to the second/second display area DA2-2.

Although not shown in FIG. 1, a peripheral area may be further positioned outside the display area DA. Also, FIG. 1 shows the display panel for a mobile phone, but the present embodiment may be applied as long as it is a display panel in which the optical element OS may be positioned on the back side of the display panel.

Hereinafter, the structure of the display area DA is described in more detail with reference to FIG. 2.

FIG. 2 is a schematic enlarged view of a first display area and a second display area in a light emitting display device according to an embodiment.

In FIG. 2, in the first display area DA1, e.g., the normal display area, the second/first display area DA2-1, e.g., the intermediate display area, and the second/second display area DA2-2, e.g., the transparent display area, according to an embodiment, and the structuring and the connection structure of the pixel circuit unit and the light-emitting element configuring the pixel PX, are shown.

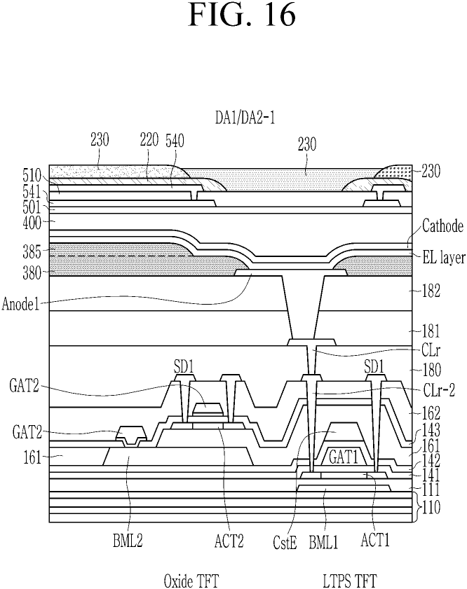

First, in the first display area DA1, e.g., the normal display area, a plurality of light-emitting elements EDrl, EDgl, and EDb1 and a plurality of pixel circuit units PCrl, PCgl, and PCb1 are formed of the same number. The plurality of light-emitting elements EDrl, EDgl, and EDb1 are sometimes referred to as a light-emitting element for a normal display area and the plurality of pixel circuit units PCrl, PCgl, and PCb1 are sometimes referred to as a pixel circuit unit for a normal display area. In FIG. 2, the pixel circuit units PCrl, PCgl, and PCb1 of the first display area DA1 are schematically illustrated in a rectangle shape, and the plurality of light-emitting elements EDrl, EDgl, and EDb1 are illustrated in a rhombus or octagon shape. The plurality of light-emitting elements EDrl, EDgl, and EDb1 are positioned on the front, sometimes called the upper side, of each of the connected pixel circuit units PCrl, PCgl, and PCb1 so that they are shown to overlap the pixel circuit units PCrl, PCgl, and PCb1 on a plane. In addition, connection parts CLr, CLg, and CLb extending from the plurality of light-emitting elements EDrl, EDgl, and EDb1 are shown so that the plurality of light-emitting elements EDrl, EDgl, and EDb1 to which the pixel circuit units PCrl, PCgl, and PCb1 are connected are clearly shown. The plurality of light-emitting elements EDrl, EDgl, and EDb1 include an anode, an emission layer, and a cathode, e.g., refer to FIG. 16. The planar shape of the light-emitting element has the shape of a rhombus or a hexagon in the embodiment shown in FIG. 2, and may have various other shapes such as a circle and a hexagon. Here, the connection parts CLr, CLg, and CLb may be formed of a transparent conductive material or may be formed of a non-transparent conductive material such as a metal.

In the embodiment of FIG. 2, four pixels are repeatedly arranged as a unit pixel. Four pixels constituting one unit pixel consist of one red pixel, one blue pixel, and two green pixels. However, according to an embodiment, at least one red pixel, at least one green pixel, and at least one blue pixel may be included. Also, in the embodiment of FIG. 2, each row has a structure in which the positions of the red light-emitting element EDr1 and the blue light-emitting element EDb1 are changed. However, numerous variations are possible in the number and structuring of the pixels or the light-emitting elements.

In the second/first display area DA2-1, e.g., the intermediate display area, of the second display area DA2, a plurality of pixel circuit units PCr2-1, PCr2-2, PCg2-1, PCg2-2, PCb2-1, and PCb2-2 and a plurality of light-emitting elements EDr2-1, EDg2-1, and EDb2-1 are positioned. The plurality of pixel circuit units PCr2-1, PCr2-2, PCg2-1, PCg2-2, PCb2-1, and PCb2-2 of the second/first display area DA2-1, e.g., the intermediate display area, is divided into pixel circuit units PCr2-1, PCg2-1, and PCb2-1 for the second/first display area DA2-1 and the pixel circuit units PCr2-2, PCg2-2, and PCb2-2 for the second/second display area DA2-2. The pixel circuit units PCr2-1, PCg2-1, and PCb2-1 for the second/first display area DA2-1 are sometimes referred to as the pixel circuit unit for the intermediate display area and the pixel circuit units PCr2-2, PCg2-2, and PCb2-2 for the second/second display area DA2-2 are sometimes referred to as the pixel circuit unit for the transparent display area. The pixel circuit units PCr2-1, PCg2-1, and PCb2-1 for the second/first display area DA2-1 are each a pixel circuit unit transmitting the light emission current to the light-emitting elements EDr2-1, EDg2-1, and EDb2-1 for a plurality of second/first display areas positioned in the second/first display area DA2-1, e.g., , e.g., the intermediate display area. The light-emitting elements EDr2-1, EDg2-1, and EDb2-1 are sometimes referred to as the light-emitting element for the intermediate display area. The pixel circuit units PCr2-1, PCg2-1, and PCb2-1 for the second/first display area DA2-1 and the light-emitting elements EDr2-1, EDg2-1, and EDb2-1 for the second/first display area DA2-1 may have a one-to-one correspondence.

On the other hand, the pixel circuit units PCr2-2, PCg2-2, and PCb2-2 for the second/second display area DA2-2 are positioned in the second/first display area DA2-1, e.g., the intermediate display area, but generate the light emission current to be transmitted to the light-emitting elements EDr2-2, EDg2-2, and EDb2-2 for the second/second display area DA2-2 positioned in the second/second display area DA2-2, e.g., the transparent display area.

The pixel circuit units PCr2-1, PCg2-1, and PCb2-1 for the second/first display area DA2-1 and the pixel circuit units PCr2-2, PCg2-2, and PCb2-2 for the second/ second display area DA2-2 have the same planar structure and circuit structure as each other except for the structure connected to the light-emitting element.

In the embodiment of FIG. 2, three pixel circuit units PCr2-1, PCg2-1, and PCb2-1 for the second/first display area DA2-1 are continuously formed in the first direction DR1 and three pixel circuit units PCr2-2, PCg2-2, and PCb2-2 for the second/second display area DA2-2 are positioned near the second/second display area DA2-2. At this time, only red and blue pixel circuit units are positioned in one row, and only green pixel circuit units are positioned in another row. According to an embodiment, the pixel circuit units PCr2-1, PCg2-1, and PCb2-1 for second/first display area DA2-1 and the pixel circuit units PCr2-2, PCg2-2, and PCb2-2 for the second/second display area DA2-2 may be disposed alternately one by one. According to an embodiment, the pixel structuring of the first display area DA1 may be the same. The structuring and number of the pixel circuit units may vary according to the embodiment.

In the second/second display area DA2-2, e.g., the transparent display area, the pixel circuit unit is not formed, the light-emitting elements EDr2-2, EDg2-2, and EDb2-2 for the second/second display area DA2-2, the transparent connection wirings TCLr, TCLg, and TCLb connected to the light-emitting elements EDr2-2, EDg2-2, and EDb2-2, and the light transmission area LTA are formed. The light-emitting elements EDr2-2, EDg2-2, and EDb2-2 for the second/second display area DA2-2 are sometimes referred to as the light-emitting elements for the transparent display area.

In FIG. 2, in the second/second display area DA2-2, e.g., the transparent display area, the light-emitting elements EDr2-2, EDg2-2, and EDb2-2 for the second/second display area DA2-2 and the transparent connection wirings TCLr, TCLg, and TCLb are shown, and the part where any one is not shown corresponds to the light transmission area LTA. Here, the portion corresponding to the pixel circuit unit and the light-emitting element in the light transmission area LTA may be formed as an inorganic insulating layer without including an organic layer. According to the embodiment, the light transmission area LTA may include an organic layer in an encapsulation layer, e.g., refer to an encapsulation layer 400 of FIG. 16, positioned on the light transmission area LTA, and may include only an inorganic insulating layer except for the encapsulation layer.

The light-emitting elements EDr2-2, EDg2-2, and EDb2-2 for one second/second display area DA2-2 are connected to the pixel circuit units PCr2-2, PCg2-2, and PCb2-2 for one second/second display area DA2-2 positioned in the second/first display area DA2-1 through one of transparent connection wirings TCLr, TCLg, and TCLb. The transparent connection wirings TCLr, TCLg, and TCLb are connected to the pixel circuit units PCr2-2, PCg2-2, and PCb2-2 for the second/second display area DA2-2 positioned in the second/first display area DA2-1, e.g., the intermediate display area, to receive the light emission current to be transmitted to the light-emitting elements EDr2-2, EDg2-2, and EDb2-2 for the second/second display area DA2-2. Also, the transparent connection wirings TCLr, TCLg, and TCLb are formed of the transparent conductive material so that the transparent region of the second/second display area DA2-2, e.g., the transparent display area, increases and the light transmittance of the second/second display area DA2-2 also increases. According to this structure, the second/second display area DA2-2, e.g., the transparent display area, may improve the performance of the motion imaged or detected by the optical element OS on the back. According to an embodiment, the transparent connection wirings TCLr, TCLg, and TCLb may be formed of an opaque metal in the second/first display area DA2-1 and may be formed of the transparent conductive material only in the second/second display area DA2-2, e.g., the transparent display area.

In the embodiment of FIG. 2, the second/first display area DA2-1, e.g., the intermediate display area, is positioned between the first display area DA1 and the second/second display area DA2-2, e.g., the transparent display area, in the first direction DR1. That is, the first display area DA1, e.g., the normal display area, the second/first display area DA2-1, e.g., the intermediate display area, and second/second display area DA2-2, e.g., the transparent display area, are sequentially positioned along the first direction DR1.

According to an embodiment, wiring, e.g., a scan line and an initialization control line, etc., required in the second/first display area DA2-1, e.g., the intermediate display area, or the first display area DA1, e.g., the normal display area, may pass through the second/second display area DA2-2, e.g., the transparent display area. The passing wiring may include a transparent conductive material, and may be formed of a non-transparent metal according to an embodiment. According to the embodiment, the passing wiring may also be positioned along the outer edge of the second/second display area DA2-2, e.g., the transparent display area.

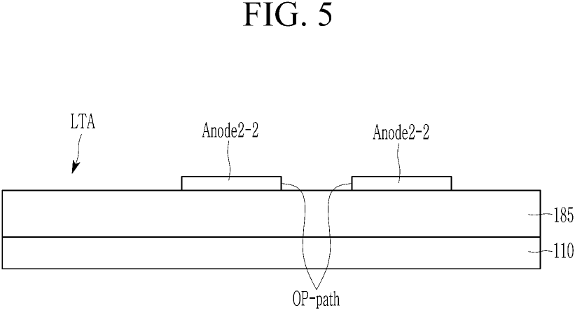

On the other hand, in FIG. 2, the pixel circuit units PCr2-1, PCr2-2, PCg2-1, PCg2-2, PCb2-1, and PCb2-2 positioned in the second display area DA2 are shown twice as large compared to the pixel circuit units PCrl, PCgl, and PCb1 positioned in the first display area DA1 in the first direction DR1, and thus the area is doubled. As described above, if the area occupied by the pixel circuit unit is large, the size, e.g., a width or a length of the channel, of the transistor such as the driving transistor positioned inside the pixel circuit unit or the size, e.g., capacitance size, of the capacitor is also formed. As a result, the size of the output current output from the resulting pixel circuit unit is also large. According to FIG. 2, the light-emitting elements EDr2-1, EDg2-1, EDb2-1, EDr2-2, EDg2-2, and EDb2-2 positioned in the second display area DA2 are also shown larger than the emitting elements EDrl, EDgl, and EDb1 positioned in the first display area DA1. If the light-emitting element is large, the output current to drive it also needs to be large. Therefore, to drive the larger light-emitting elements EDr2-1, EDg2-1, EDb2-1, EDr2-2, EDg2-2, and EDb2-2 positioned in the second display area DA2, the pixel circuit units PCr2- 1, PCr2-2, PCg2-1, PCg2-2, PCb2-1, and PCb2-2 are also formed to be large to generate the large output current. On the other hand, in the embodiment like FIG. 5, a plurality of light-emitting elements may be connected for one pixel circuit unit of the second display area DA2, in this case, the size of the light-emitting element may be the same size as that of the light-emitting element of the first display area DA1. As above-described, unlike the first display area DA1, the pixel circuit unit may be largely formed so that a plurality of light-emitting elements are connected to the pixel circuit unit of the second display area DA2 to transmit the output current to a plurality of light-emitting elements. The area of the pixel circuit unit of the second display area DA2 may be four times larger than the area of the pixel circuit unit of the first display area DA1, and the difference of the area may be various according to embodiments.

According to an embodiment of FIG. 2, based on the unit area, the sum of the number of the pixel circuit units PCr2-1, PCg2-1, and PCb2-1 for the second/first display area DA2-1 positioned in the second/first display area DA2-1, e.g., the intermediate display area, and the number of the pixel circuit units PCr2-2, PCg2-2, and PCb2-2 for the second/second display area DA2-2 may be half of the number of the pixel circuit units PCrl, PCgl, and PCb1 positioned in the first display area DA1, e.g., the normal display area. Since the number of the pixel circuit units PCr2-1, PCg2-1, and PCb2-1 for the second/first display area DA2-1 positioned in the second/first display area DA2-1, e.g., the intermediate display area, and the number of the pixel circuit units PCr2-2, PCg2-2, and PCb2-2 for the second/second display area DA2-2 may be the same, the number of the light-emitting elements positioned in the second/first display area DA2-1, e.g., the intermediate display area, or the second/second display area DA2-2, e.g., the transparent display area, may be ¼ of the number of the light-emitting elements positioned in the first display area DA1, e.g., the normal display area. Therefore, the pixel number (PPI or pixels per inch) value per inch of the pixels positioned in the second display area DA2 is smaller than the pixel number (PPI) value per inch of the pixels formed in the first display area DA1. As such, when the number of light-emitting elements in the second display area DA2 is smaller than the number of light-emitting elements in the first display area DA1 based on the unit area, the area of the light-emitting elements in the second display area DA2 may be formed larger than the area of the light-emitting element of the first display area DA1.

On the other hand, according to an embodiment, based on the unit area, the sum of the number of the pixel circuit units PCr2-1, PCg2-1, and PCb2-1 for the second/first display area DA2-1 and the number of the pixel circuit units PCr2-2, PCg2-2, and PCb2-2 for the second/second display area DA2-2 positioned in the second/first display area DA2-1, e.g., the intermediate display area, may be the same as the number of the pixel circuit units PCrl, PCgl, and PCb1 positioned in the first display area DA1, e.g., the normal display area. In this case, based on the unit area, the number of the light-emitting elements positioned in the second/first display area DA2-1, e.g., the intermediate display area, or the second/second display area DA2-2, e.g., the transparent display area, may be ½ of the number of the light-emitting elements positioned in the first display area DA1, e.g., the normal display area. On the other hand, according to an embodiment, the number of the light-emitting elements positioned in the second/first display area DA2-1, e.g., the intermediate display area, or the second/second display area DA2-2, e.g., the transparent display area, may be different and a number ratio of the light-emitting elements between the display areas may be various. On the other hand, according to an embodiment, a plurality of light-emitting elements connected to one pixel circuit unit are formed in the second display area DA2 so that the pixel number value per inch (PPI) of the first display area DA1 and the pixel number value per inch (PPI) formed in the second display area DA2 may be the same. In the case of having the same pixel number per inch (PPI) as described above, the size of the light-emitting element of the second display area DA2 and the size of the light-emitting element of the first display area DA1 may be formed to be the same.

In the above, the structure of the first display area DA1 and the second display area DA2 was described as a whole based on FIG. 2.

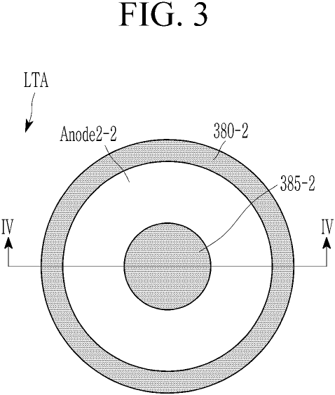

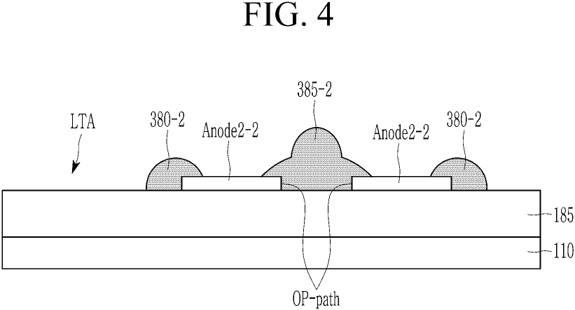

Hereinafter, the anode included in the light-emitting elements EDr2-2, EDg2-2, and EDb2-2 for the second/second display area DA2-2 positioned in the second/second display area DA2-2, e.g., the transparent display area, and the structure around the anode are described with reference to FIG. 3 and FIG. 4 in more detail.

FIG. 3 is a top plan view of an anode and a periphery of the anode of a second display area according to an embodiment. FIG. 4 is a cross-sectional view taken along a line IV-IV of FIG. 3.

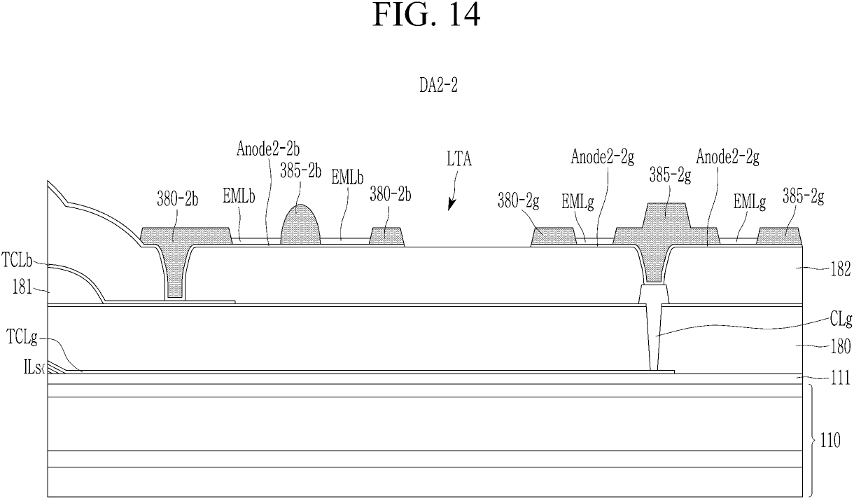

FIG. 3 and FIG. 4 shows the anode Anode2-2 for one second/second display area DA2-2 positioned in the second/second display area DA2-2, e.g., the transparent display area, and the first light blocking part 385-2 and the second light blocking part 380-2 positioned around the anode Anode2-2. The part where the anode Anode2-2 for the second/ second display area DA2-2, the first light blocking part 385-2, and the second light blocking part 380-2 are not positioned correspond to the light transmission area LTA. The anode Anode2-2 is sometime referred to as an anode for the transparent display area. On the other hand, FIG. 4 shows only an upper organic layer 185 and a substrate 110 under the anode Anode2-2 of the second/second display area DA2-2, however this is schematic, and according to an embodiment, the second/second display area DA2-2, e.g., the transparent display area, may have the same structure as FIG. 14.

Referring to FIG. 3 and FIG. 4, in the second/second display area DA2-2, e.g., the transparent display area, the anode Anode2-2 for the second/second display area DA2-2 is positioned on the upper organic layer 185. In FIG. 3, the anode Anode2-2 for the second/second display area DA2-2 is shown as a circle, but it may have a rhombus shape as shown in FIG. 2 or a structure with chamfered corners, and may also have various polygonal shapes such as hexagons and octagons.

Referring to FIG. 4, an opening OP-path is formed in the anode Anode2-2 for the second/ second display area DA2-2, and the opening OP-path may be surrounded by the anode Anode2-2 of the second/second display area DA2-2. The anode Anode2-2 for the second/second display area DA2-2 includes the inner side forming the boundary of the opening OP-path and the exterior side forming the outer boundary. The area occupied by the opening OP-path among the entire area surrounded by the exterior side of the anode Anode2-2 for the second/second display area DA2-2 may be 5% or more and 20% or less. If it is less than 5%, it may be difficult for the first light blocking part 385-2 formed while covering the opening OP-path to be formed with a sufficient height, and if it is more than 20%, the light emitting area may be reduced, and there is also a drawback that the area of the light transmission area LTA is also reduced.

The first light blocking part 385-2 covering the opening OP-path of the anode Anode2-2 for the second/second display area DA2-2 and covering the inner side of the anode Anode2-2 for the second/second display area DA2-2 and some regions is positioned.

In addition, the second light blocking part 380-2 covering the exterior side of the anode Anode2-2 for the second/second display area DA2-2 and surrounding the anode Anode2-2 for the second/second display area DA2-2 along the exterior side is positioned.

The first light blocking part 385-2 and the second light blocking part 380-2 may include a light blocking material, and may be formed of an organic material having a black color. Also, for the first light blocking part 385-2 and the second light blocking part 380-2, corresponding to a partition wall, e.g., refer to a partition wall 380 of FIG. 16, and/or a spacer, e.g., refer to a spacer 385 of FIG. 16, having an opening exposing the anode formed in the first display area DA1, e.g., the normal display area, and the second/first display area DA2-1, e.g., the intermediate display area, the partition wall, e.g., refer to the partition wall 380 of FIG. 16, and the spacer, e.g., refer to the spacer 385 of FIG. 16, formed in the first display area DA1, e.g., the normal display area, and the second/first display area DA2-1, e.g., the intermediate display area, may also include a light blocking material and be formed of an organic material having a black color. Here, the light blocking material may include a resin or paste, carbon black, carbon nanotubes, a black dye, metal particles, including, for example, nickel, aluminum, molybdenum, and alloys thereof, metal oxide particles, for example, chromium nitride, and the like. In addition, the first light blocking part 385-2, the second light blocking part 380-2, the partition wall, and the spacer may have a characteristic that light is absorbed/blocked without being reflected. In addition, according to the embodiment, the first light blocking part 385-2, the second light blocking part 380-2, the partition wall, and the spacer may have a characteristic in which a part covered by a mask is removed using an organic material of a negative type.

Referring to FIG. 4, in the embodiment of FIG. 3, the first light blocking part 385-2 formed corresponding to the opening OP-path of the anode Anode2-2 for the second/ second display area DA2-2 and the second light blocking part 380-2 surrounding the anode Anode2-2 for the second/second display area DA2-2 may have different heights, that is, the heights of the highest parts are different.

In the embodiment of FIG. 4, the first light blocking part 385-2 is formed high and also plays a role of a spacer, and the second light blocking part 380-2 is formed lower than the first light blocking part 385-2, but it is formed to a thickness that does not transmit light. Here, the height of the first light blocking part 385-2 may be substantially the same as the height of the spacer, e.g., refer to the spacer 385 of FIG. 16, formed in the first display area DA1, e.g., the normal display area, and the second/first display area DA2-1, e.g., the intermediate display area, and the height of the second light blocking part 380-2 may be substantially the same as the height of the partition wall, e.g., refer to the partition wall 380 in FIG. 16, formed in the first display area DA1, e.g., the normal display area, and the second/first display area DA2-1, e.g., the intermediate display area. On the other hand, referring to FIG. 4, the first light blocking part 385-2 may be divided into a peripheral part and a central part,

The center part is formed high so that it may be formed substantially equal to the height of the spacer, e.g., refer to the spacer 385 of FIG. 16, formed in the first display area DA1, e.g., the normal display area, and the second/first display area DA2-1, e.g., the intermediate display area, but the periphery is formed low so that it may be substantially the same as the height of the partition wall, e.g., refer to the partition wall 380 of FIG. 16, formed in the second light blocking part 380-2, and the first display area DA1, e.g., the normal display area, and the second/first display area DA2-1, e.g., the intermediate display area.

The anode Anode2-2 for the second/second display area DA2-2 of the second/second display area DA2-2, e.g., the transparent display area, is included in the light-emitting elements EDr2-2, EDg2-2, and EDb2-2 for the second/second display area DA2-2. In a plane view of FIG. 3, the anode Anode2-2 part for the second/second display area DA2-2 exposed by the first light blocking part 385-2 and second light blocking part 380-2 may correspond to the planar position of the light-emitting elements EDr2-2, EDg2-2, and EDb2-2 for the second/second display area DA2-2. Also, the planar shape of the light-emitting elements EDr2-2, EDg2-2, and EDb2-2 for the second/second display area DA2-2 shown in FIG. 2 may correspond to the combined shape of the shape of the second light blocking part 380-2 positioned outside as well as the anode Anode2-2 for the second/second display area DA2-2. On the other hand, if the area of the anode Anode2-2 for the second/second display area DA2-2 exposed by the first light blocking part 385-2 and the second light blocking part 380-2 is large, the planar area of the light-emitting elements EDr2-2, EDg2-2, and EDb2-2 for the second/second display area DA2-2 may also be large. The light-emitting elements EDr2-2, EDg2-2, and EDb2-2 for the second/second display area DA2-2 may further include an emission layer and a cathode as well as the anode Anode2-2 for the second/second display area DA2-2.

The cathode may be formed on the light transmission area LTA, the first light blocking part 385-2, and the second light blocking part 380-2 as well as one anode Anode2-2 for the second/second display area DA2-2, and may be formed over the entire region of the second/second display area DA2-2, e.g., the transparent display area. However, according to an embodiment, the cathode may not be formed in some regions of the light transmission area LTA. Meanwhile, the cathode is formed entirely in the first display area DA1, e.g., the normal display area, and the second/first display area DA2-1, e.g., the intermediate display area.

On the other hand, the emission layer may be positioned only on the anode Anode2-2 for the second/second display area DA2-2 exposed by the first light blocking part 385-2 and the second light blocking part 380-2, and may be positioned on the side surface of the partial first light blocking part 385-2 and the second light blocking part 380-2. However it may not cover the first light blocking part 385-2 and the second light blocking part 380-2 and may also not be positioned in the light transmission area LTA. On the other hand, the emission layer, in the first display area DA1, e.g., the normal display area, and the second/first display area DA2-1, e.g., the intermediate display area, may only be formed on the anode part exposed by the spacer, e.g., refer to the spacer 385 of FIG. 16, and the partition wall, e.g., refer to the partition wall 380 of FIG. 16, corresponding to the first light blocking part 385-2 and the second light blocking part 380-2.

Meanwhile, the light-emitting elements EDr2-2, EDg2-2, and EDb2-2 for the second/second display area DA2-2 may further include a functional layer in addition to the anode Anode2-2 for the second/second display area DA2-2, the emission layer, and the cathode. Here, the functional layer may include auxiliary layers such as an electron injection layer, an electron transport layer, a hole transport layer, and a hole injection layer. The hole injection layer and the hole transport layer may be positioned under the emission layer, and the electron transport layer and the electron injection layer may be positioned on the emission layer. The functional layer may be formed not only on the anode Anode2-2 for the second/second display area DA2-2, but also on the light transmission area LTA, the first light blocking part 385-2, and the second light blocking part 380-2, and may be formed over the entire region of the second/second display area DA2-2, e.g., the transparent display area. In addition, the functional layer may be entirely formed in the first display area DA1, e.g., the normal display area, and the second/first display area DA2-1, e.g., the intermediate display area.

For reference, the light transmission area LTA does not exist in the first display area DA1, e.g., the normal display area, and the second/first display area DA2-1, e.g., the intermediate display area, so the partition wall, e.g., refer to the partition wall 380 of FIG. 16, corresponding to the first light blocking part 385-2 and the second light blocking part 380-2 may be entirely positioned except for the opening exposing the anode, and the spacer, e.g., refer to the spacer 385 of FIG. 16, may be positioned on a part of the partition wall.

On the other hand, referring to FIG. 4, although the stacked structure of the light transmission area LTA is shown for simplicity, the light transmission area LTA may include a semiconductor or a metal, a light blocking member such as a black matrix, and a color filter so that light may be transmitted without blocking, and when wiring is formed, it may be formed of a transparent conductive material.

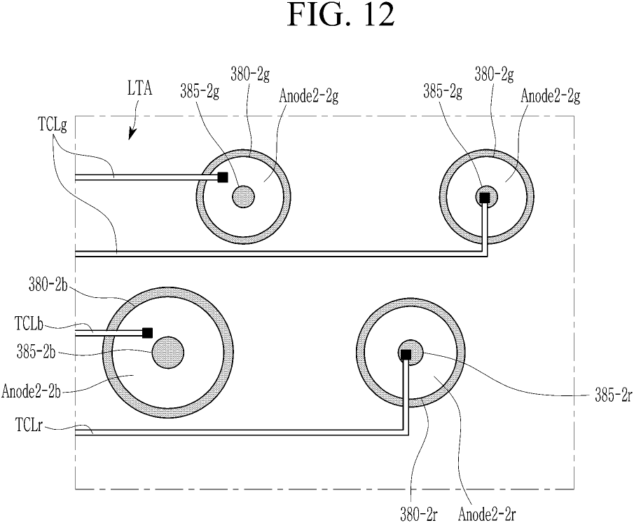

The light transmission area LTA may be stacked with only a transparent material, and the transparent material includes an inorganic or organic layer and may additionally include a functional layer. In addition, it may be positioned in the light transmission area LTA as wiring, e.g., a transparent connection wiring such as the transparent connection wirings TCLr, TCLg, TCLb in FIG. 12, etc., formed of a transparent conductive material or a cathode. An encapsulation layer, e.g., refer to the encapsulation layer 400 of FIG. 16, may be positioned above the light transmission area LTA, and the encapsulation layer may include at least one inorganic layer and at least one organic layer. According to an embodiment, the light transmission area LTA may only include an inorganic layer or an organic layer except for the encapsulation layer, thus reducing a transmittance reduction generated on the boundary of two layers having large differences of refractive index. The inorganic or organic layer formed in the light transmission area LTA may be an inorganic or organic layer used in the first display area DA1, e.g., the normal display area, and the second/first display area DA2-1, e.g., the intermediate display area, and according to an embodiment, an inorganic layer or an organic layer formed only in the second/second display area DA2-2, e.g., the transparent display area, may be included.

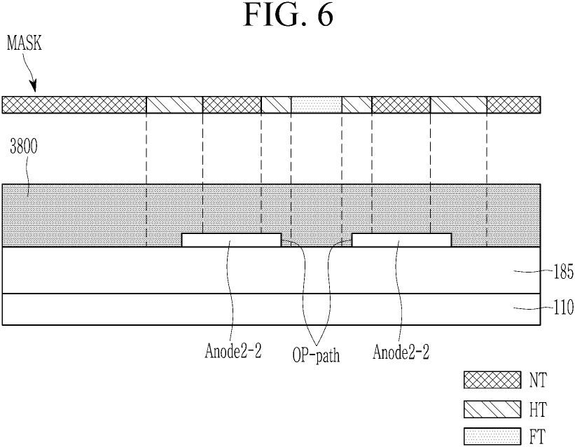

Hereinafter, the manufacturing method of the embodiment of FIG. 3 and FIG. 4 is described in detail with reference to FIG. 5 and FIG. 6.

FIG. 5 and FIG. 6 are cross-sectional views sequentially showing a manufacturing method of an anode of a second display area and a periphery of the anode according to an embodiment.

First, FIG. 5 shows a state that a material for an anode formation is stacked on an upper organic layer 185 and patterned by using a mask, and as a result, an anode Anode2-2 for the second/second display area is formed of a structure having an opening OP-path inside.

Here, the manufacturing process of the anode Anode2-2 for the second/second display area may proceed together with the process of forming the anode in the first display area DA1, e.g., the normal display area, and the second/first display area DA2-1, e.g., the intermediate display area, and may be formed of the same material. The material for forming the anode may be the same as the material forming the anode in the first display area DA1, e.g., the normal display area, and the second/first display area DA2-1, e.g., the intermediate display area, and may be composed of a single layer including a transparent conductive oxide layer and a metal material or multiple layers including them. Here, the transparent conductive oxide film may include Indium Tin Oxide (ITO), poly-ITO, Indium Zinc Oxide (IZO), Indium Gallium Zinc Oxide (IGZO), Indium Tin Zinc Oxide (ITZO), and the like, and the metal material may include silver (Ag), molybdenum (Mo), copper (Cu), gold (Au), and aluminum (Al).

Next, as shown in FIG. 6, a material 3800 for a blocking part is stacked and then exposed using a mask MASK having a transflective region HT, sometimes called a half-tone region HT.

Here, the material 3800 for the blocking part may be the same as a material for a partition wall and a spacer in the first display area DA1, e.g., the normal display area, and the second/first display area DA2-1, e.g., the intermediate display area, and a first light blocking part 385-2, a second light blocking part 380-2, a partition wall, and a spacer may be formed through the same process.

The material 3800 for the blocking part may be an organic material including a light blocking material or having a black color, and the material 3800 for the blocking part may include carbon black, carbon nanotubes, a resin or paste including a black dye, or metal particles, for example, nickel, aluminum, molybdenum, and alloys, metal oxide particles, for example, chromium nitride, and the like. In addition, the material 3800 for the blocking part may have a characteristic that light is absorbed/blocked without being reflected, and the material 3800 for the blocking part in the embodiment of FIG. 6 may be an organic material of a negative type, so it may have a characteristic in which the part covered by the mask is removed.

In FIG. 6, the mask MASK is divided into a light-transmitting region FT, the half-tone region HT, and a light blocking region NT. Here, in the half-tone region HT, the transmittance of light may be reduced by using a slit, or a material having low transmittance may be included.

Since the material 3800 for the blocking part is formed of the organic material of the negative type, the material 3800 for the blocking part is all removed on the part corresponding to the light blocking region NT of the mask MASK, the material 3800 for the blocking part partially remains on the part corresponding to the half-tone region HT so that the height is lowered, and the material 3800 for the blocking part is not removed and is formed highly on the part corresponding to the light-transmitting region FT.

When exposing and then developing the material 3800 for the blocking part using mask MASK, as shown in FIG. 4, the pattern of a first light blocking part 385-2 and a second light blocking part 380-2 is completed. Referring to FIG. 4, among the material 3800 for the blocking part, a center part having a high height is formed among the first light blocking part 385-2 on the part exposed through the light-transmitting region FT. A second light blocking part 380-2 and a periphery part among the first light blocking part 385-2 are formed on the part exposed through the half-tone region HT among the material 3800 for the blocking part. According to an embodiment, the entire first light blocking part 385-2 may be exposed to the light-transmitting region FT of the mask MASK to have a high height overall, and may not include the peripheral portion.

The embodiment of FIG. 3 and FIG. 4 has a structure in which an opening OP-path is formed on the anode Anode2-2 for the second/second display area of the second/second display area DA2-2, e.g., the transparent display area.

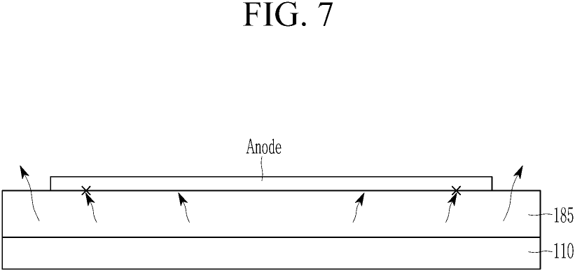

Hereinafter, the merit of forming the opening OP-path in the anode Anode2-2 for the second/second display area compared with a comparative example that does not form an opening OP-path in the anode Anode2-2 for the second/second display area is described through FIG. 7.

FIG. 7 is a cross-sectional view according to a comparative example.

FIG. 7 shows the comparative example without having an opening while forming the anode Anode on the organic layer.

Comparing FIG. 5 and FIG. 7, the opening OP-path is formed in the anode Anode2-2 for the second/second display area, but in the comparative example, it may be confirmed that there is no opening.

In FIG. 7, if the anode Anode is formed on the organic layer, the remaining moisture or gas, sometimes referred to as residual moisture, escapes to the upper part from the underlying organic layer due to the heat generated during a heat treatment or the formation of the anode Anode. However a certain area is blocked by the anode, and the residual moisture cannot escape from some regions. The organic layer with such residual moisture has a different thickness compared to the organic layer without the residual moisture. Accordingly, a defect, e.g., a shrinkage defect, in which a step is caused in the overlying layer occurs. In particular, when the shrinkage defect occurs in the light transmission area LTA, there is a problem that the light transmittance is reduced, and as a result, the light provided to the optical element OS such as a camera or an optical sensor is also reduced, and the performance of the optical element OS deteriorates.

However, as shown in FIG. 5, when the opening OP-path is formed on the anode Anode2-2 for the second/second display area, the remaining moisture positioned at the lower part of the anode Anode2-2 for the second/second display area is also discharged by using the opening OP-path as a gas passage, e.g., an outgas path, and then the height becomes constant with other parts. For proper discharge of the residual moisture, the larger the opening OP-path formed on the anode Anode2-2 for the second/second display area, the better, however in that case, there is a drawback in that the light emitting region that emits light is reduced, so it is formed to be 5% or more and 20% or less, so that the image may be sufficiently displayed while removing the residual moisture.

In the above, the embodiment in which the first light blocking part 385-2 formed corresponding to the opening OP-path of the anode Anode2-2 for the second/second display area is formed high, and the second light blocking part 380-2 surrounding the anode Anode2-2 for the second/second display area is formed, have been described. In addition, the anode Anode2-2 for the second/second display area having a circular structure has been described in the embodiment.

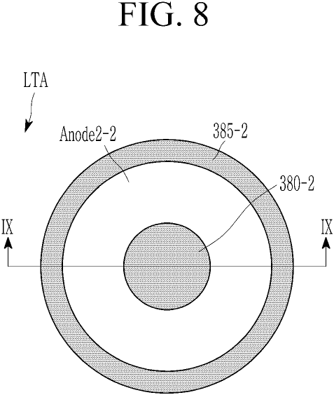

However, according to an embodiment, the height of the first light blocking part may be lower than the height of the second light blocking part, and the shape of the anode Anode2-2 for the second/second display area may be changed. For this, various embodiments are described through FIG. 8 to FIG. 11.

FIG. 8 to FIG. 11 are views of an anode and a periphery of the anode of a second display area according to an embodiment.

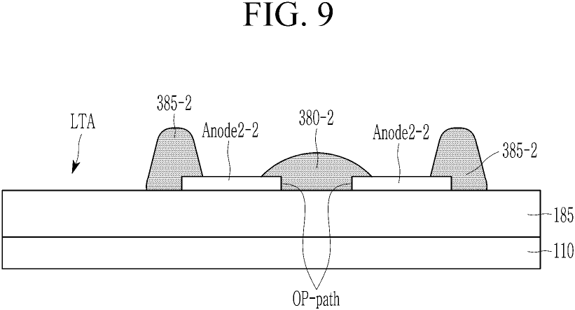

First, other embodiments are described with reference to FIG. 8 and FIG. 9. FIG. 9 is a cross-sectional view taken along a line IX-IX of FIG. 8.

In the embodiment of FIG. 8 and FIG. 9, unlike the embodiment of FIG. 3 and FIG. 4, the first light blocking part 380-2 formed corresponding to the opening OP-path of the anode Anode2-2 for the second/ second display area is formed with a lower height, however the second light blocking part 385-2 surrounding the anode Anode2-2 for the second/second display area is formed with a high height. In the embodiment of FIG. 8 and FIG. 9, there is a difference that the second light blocking part 385-2 having the height corresponding to the spacer of the first display area DA1, e.g., the normal display area, and the second/first display area DA2-1, e.g., the intermediate display area, is formed at the part surrounding the anode Anode2-2 for the second/second display area. In the embodiment of FIG. 8 and FIG. 9, even if light is emitted from the emission layer positioned on the anode Anode2-2 for the second/second display area, the light is not provided to the side beyond a certain angle due to the high second light blocking part 385-2. That is, in the embodiment of FIG. 8 and FIG. 9, the light of the light-emitting elements EDr2-2, EDg2-2, and EDb2-2 for the second/second display area may not be provided to the side beyond a certain angle, so it may be used more appropriately in the light emitting display device by which the user is viewed on the more front surface.

In the above, the embodiment in which the planar shape of the anode Anode2-2 for the second/second display area is all circular has been described.

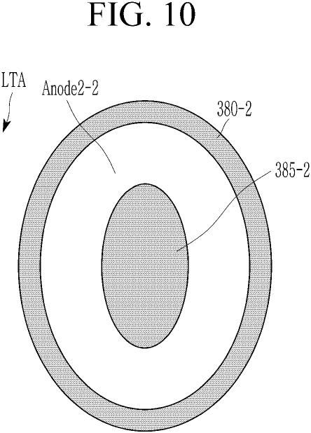

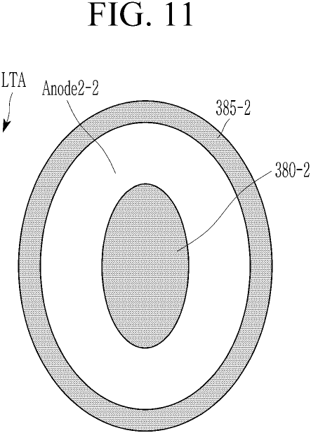

However, as shown in FIG. 10 and FIG. 11, it may have an elliptical structure, and may have various other polygonal structures.

In the embodiment of FIG. 10, like the embodiment of FIG. 3 and FIG. 4, the first light blocking part 385-2 formed corresponding to the opening OP-path of the anode Anode2-2 for the second/second display area is formed of a high height. In the embodiment of FIG. 11, like that of FIG. 8 and FIG. 9, the first light blocking part 385-2 formed corresponding to the opening OP-path of the anode Anode2-2 for the second/second display area is formed of a low height. As a result, the cross-section of FIG. 10 may be the same as FIG. 4, and the cross-section of FIG. 11 may be the same as FIG. 9.

The anode Anode2-2 for the second/second display area of the embodiment described above is connected to the pixel circuit units PCr2-2, PCg2-2, and PCb2-2 for the second/second display area positioned in the second/first display area DA2-1, e.g., the intermediate display area, through the transparent connection wirings TCLr, TCLg, and TCLb and the connection structure is described in detail through FIG. 12 to FIG. 14. The pixel circuit units PCr2-2, PCg2-2, and PCb2-2 for the second/second display area are sometimes referred to as the pixel circuit unit for the transparent display area.

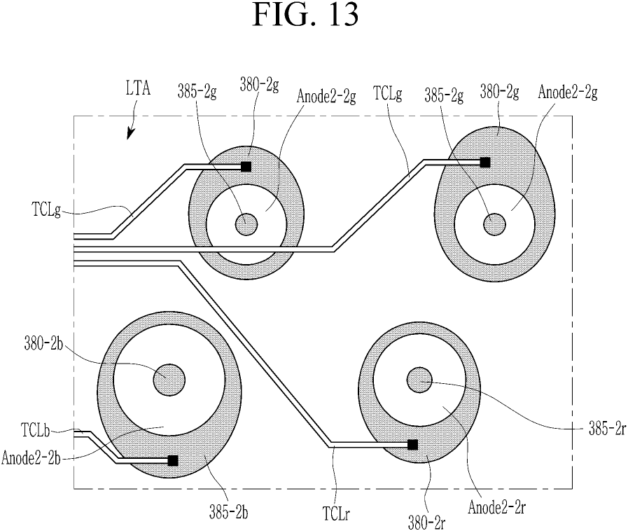

First, the planar connection structure according to an embodiment is described with reference to FIG. 12 and FIG. 13.

FIG. 12 and FIG. 13 are views showing a connection structure of an anode of a second display area according to an embodiment.

In FIG. 12 and FIG. 13, the anode Anode2-2 for the second/second display area, and the first light blocking part 385-2 and the second light blocking part 380-2 positioned inside and around the anode Anode2-2, are distinguished and shown for each color. That is, the anode Anode2-2 for the second/second display area is divided into a red anode Anode2-2r for the second/second display area, a green anode Anode2-2g for the second/second display area, and a blue anode Anode2-2b for the second/second display area. r, g, and b are respectively added on the ends of the reference numeral for each of the first light blocking part 385-2 and the second light blocking part 380-2 positioned inside and around the anode Anode2-2 to represent the light blocking part positioned corresponding to the red anode Anode2-2r for the second/second display area, the green anode Anode2-2g for the second/second display area, and the blue anode Anode2-2b for the second/second display area. In addition, the transparent connection wiring is also shown for each color.

First, in the second/second display area DA2-2, e.g., the transparent display area, according to an embodiment of FIG. 12, each anode Anode2-2r, Anode2-2g, and Anode2-2b for the second/second display area is connected to the transparent connection wirings TCLr, TCLg, and TCLb extending from the second/first display area DA2-1, e.g., the intermediate display area. The part where the transparent connection wirings TCLr, TCLg, and TCLb are connected to the anodes Anode2-2r, Anode2-2g, and Anode2-2b for the second/second display area may be a region that does not overlap the first light blocking parts 385-2r, 385-2g, and 385-2b and the second light blocking parts 380-2r, 380-2g, and 380-2b on a plane.

On the other hand, in the embodiment of FIG. 13 unlike FIG. 12, the part where the transparent connection wirings TCLr, TCLg, and TCLb are connected to the anode Anode2-2r, Anode2-2g, Anode2-2b for the second/second display area may be a region overlapping the second light blocking parts 380-2r, 380-2g, and 380-2b on a plane. Also, in the embodiment of FIG. 13 unlike the embodiment of FIG. 12, the part connected to the transparent connection wirings TCLr, TCLg, and TCLb among the second light blocking parts 380-2r, 380-2g, and 380-2b are formed of the relatively wide width.

According to an embodiment, the part where the transparent connection wirings TCLr, TCLg, and TCLb are connected to the anodes Anode2-2r, Anode2-2g, and Anode2-2b for the second/second display area may be a region overlapping the first light blocking parts 385-2r, 385-2g, and 385-2b on a plane, and this embodiment is shown in the cross-sectional structure of the right of FIG. 14.

Also, the transparent connection wirings TCLr, TCLg, and TCLb have a bent structure in the embodiment of FIG. 13 and have a straight line structure of FIG. 12. According to an embodiment, the transparent connection wirings TCLr, TCLg, and TCLb may have various bent structures.

Hereinafter, the connection structure of the transparent connection wiring and the anode for the second/second display area is described through the cross-sectional structure of the second/second display area DA2-2, e.g., the transparent display area, with reference to FIG. 14.

FIG. 14 is a view showing a connection structure of an anode of a second display area according to an embodiment.

First, the light transmission area LTA among the second/second display area DA2-2, e.g., the transparent display area, of FIG. 14 has the structure in which the substrate 110, a buffer layer 111, a first organic layer 180, and a third organic layer 182 are sequentially stacked, and the transparent connection wirings TCLr, TCLg, and TCLb may be additionally positioned. Referring to the left of FIG. 14, a second organic layer 181 and a plurality of inorganic layers ILs are not formed in the second/second display area DA2-2, e.g., the transparent display area. In the first display area DA1, e.g., the normal display area, and the second/first display area DA2-1, e.g., the intermediate display area, the second organic layer 181 and the plurality of inorganic layers ILs are positioned, and other insulating layers, e.g., the buffer layer 111, the first organic layer 180, and the third organic layer 182, which are positioned in the second/second display area DA2-2, e.g., the transparent display area, are also positioned.

In the embodiment of FIG. 14, one transparent connection wiring TCLb among the transparent connection wirings TCLr, TCLg, and TCLb is positioned under the third organic layer 182, is disposed on the second organic layer 181 in the second/first display area DA2-1, e.g., the intermediate display area, and is positioned on the first organic layer 180 in the second/second display area DA2-2, e.g., the transparent display area. Also, another one transparent connection wiring TCLg among the transparent connection wirings TCLr, TCLg, and TCLb is positioned on the first organic layer 180, is positioned on the plurality of inorganic layer ILs in the second/first display area DA2-1, e.g., the intermediate display area, and is positioned on the buffer layer 111 in the second/second display area DA2-2, e.g., the transparent display area. The transparent connection wiring TCLg positioned on the buffer layer 111 may further include a connection part CLg to be connected to the anode Anode2-2g. At this time, the connection part CLg may be formed of a transparent conductive material, but the conductivity may be improved by using a metal. When the metal is used, it may be formed in a position overlapping with one of the first light blocking part and the second light blocking part on a plane because it blocks light. In the embodiment of FIG. 14, the connection part CLg overlaps the first light blocking part 385-2g on a plane. However, according to an embodiment, the structuring, the connection relationship, the connection position, etc. of the transparent connection wirings TCLr, TCLg, and TCLb and the connection part CLg may be variously modified. Also, the inorganic or organic layers formed on the second/second display area DA2-2, e.g., the transparent display area, may also include various layers.

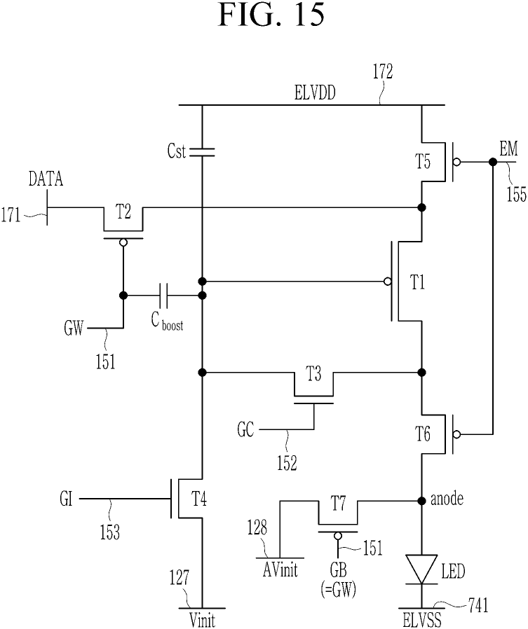

In the above, the structure of the second/second display area DA2-2, e.g., the transparent display area, was mainly examined. The second/second display area DA2-2, e.g., the transparent display area, may be formed along with the first display area DA1, e.g., the normal display area, and the second/first display area DA2-1, e.g., the intermediate display area, and then this may correspond to the stacked structure of the first display area DA1, e.g., the normal display area, and the second/first display area DA2-1, e.g., the intermediate display area. Hereinafter, two embodiments among structures of the pixel that may be formed in the first display area DA1, e.g., the normal display area, and the second/first display area DA2-1, e.g., the intermediate display area, are described with reference to FIG. 15 to FIG. 18.

Now, the circuit structure and the cross-sectional structure according to various embodiments of the pixel including the pixel circuit unit and the light-emitting element formed in the first display area DA1 are described with reference to FIG. 15 to FIG. 18. FIG. 15 to FIG. 18 below may also be applied to the structure of the second/first display area DA2-1.

First, the pixel using two semiconductor layers is described with reference to FIG. 15 and FIG. 16.

FIG. 15 is a circuit diagram of one pixel included in a light emitting display device according to an embodiment. FIG. 16 is a view showing a cross-section of a pixel according to an embodiment of FIG. 15.

First, the circuit structure of one pixel including the pixel circuit unit and the light-emitting element is described through FIG. 15.

The circuit structure shown in FIG. 15 is a circuit structure of the pixel circuit unit and the light-emitting element formed in the first display area DA1, e.g., the normal display area, and the second/first display area DA2-1, e.g., the intermediate display area.

One pixel according to the embodiment of FIG. 15 includes a plurality of transistors T1, T2, T3, T4, T5, T6, and T7, a storage capacitor Cst, a boost capacitor C_{boost}, and a light-emitting element LED, which are connected to several wirings 127, 128, 151, 152, 153, 155, 171, 172, and 741. Here, the transistors and the capacitors, which are elements other than the light-emitting element LED, constitute the pixel circuit unit. According to an embodiment, the boost capacitor C_{boost} may be omitted.

The plurality of wirings 127, 128, 151, 152, 153, 155, 171, 172, and 741 are connected to one pixel PX. A plurality of wirings includes a first initialization voltage line 127, a second initialization voltage line 128, a first scan line 151, a second scan line 152, an initialization control line 153, a light emitting control line 155, a data line 171, a driving voltage line 172, and a common voltage line 741. In the embodiment of FIG. 15, the first scan line 151 connected to the seventh transistor T7 is also connected to the second transistor T2. According to an embodiment, the seventh transistor T7 may be connected by a separate bypass control line differently from the second transistor T2.

The first scan line 151 is connected to a scan driver (not shown) to transmit a first scan signal GW to the second transistor T2 and the seventh transistor T7. A voltage of an opposite polarity to a voltage applied to the first scan line 151 may be applied to the second scan line 152 at the same timing as the signal of the first scan line 151. For example, when a negative voltage is applied to the first scan line 151, a positive voltage may be applied to the second scan line 152. The second scan line 152 transmits a second scan signal GC to the third transistor T3. The initialization control line 153 transmits an initialization control signal GI to the fourth transistor T4. The light emission control line 155 transmits a light emission control signal EM to the fifth transistor T5 and the sixth transistor T6.

The data line 171 is a wire transmitting a data voltage DATA generated from a data driver (not shown). Accordingly, a luminance emitted by the light emitting element LED is changed as a magnitude of the light emitting current transmitted to the light emitting element LED. The driving voltage line 172 applies a driving voltage ELVDD. The first initialization voltage line 127 transmits a first initialization voltage Vinit, and the second initialization voltage line 128 transmits a second initialization voltage AVinit. The common voltage line 741 applies a common voltage ELVSS to the cathode of the light emitting element LED. In the present embodiment, the voltages applied to the driving voltage line 172, the first and second initialization voltage lines 127 and 128, and the common voltage line 741 may be a constant voltage, respectively.

A transistor included in the pixel may be divided into two types of transistors. The driving transistor T1, the second transistor T2, the fifth transistor T5, the sixth transistor T6, and the seventh transistor T7 are p-type transistors including a polycrystalline semiconductor and may be turned on by a low voltage. Meanwhile, the third transistor T3 and the fourth transistor T4 are n-type transistors including an oxide semiconductor and may be turned on by a high voltage.

The driving transistor T1, also referred to as a first transistor, is a p-type transistor and has a silicon semiconductor as a semiconductor layer. It is a transistor that adjusts the magnitude of the light emitting current output to the anode of the light emitting diode LED according to the magnitude of the voltage, i.e., a voltage stored in the storage capacitor Cst, of the gate electrode of the driving transistor T1. Since the brightness of the light emitting diode LED is adjusted according to the magnitude of the light emitting current output to the anode of the light emitting diode LED, the light emitting luminance of the light emitting diode LED may be adjusted according to the data voltage DATA applied to the pixel. For this purpose, the first electrode of the driving transistor T1 is disposed to receive the driving voltage ELVDD and is connected to the driving voltage line 172 via the fifth transistor T5. Also, the first electrode of the driving transistor T1 is also connected to the second electrode of the second transistor T2 to receive the data voltage DATA. On the other hand, the second electrode of the driving transistor T1 outputs the light emitting current to the light emitting diode LED and is connected to the anode of the light emitting diode LED via the sixth transistor T6, sometimes referred to as an output control transistor. In addition, the second electrode of the driving transistor T1 is also connected to the third transistor T3 to transmit the data voltage DATA applied to the first electrode to the third transistor T3. Meanwhile, the gate electrode of the driving transistor T1 is connected to one electrode, sometimes referred to as a second storage electrode, of the storage capacitor Cst. Accordingly, the voltage of the gate electrode of the driving transistor T1 changes according to the voltage stored in the storage capacitor Cst, and the light emitting current output by the driving transistor T1 is changed. The storage capacitor Cst serves to keep the voltage of the gate electrode of the driving transistor T1 constant for one frame. Meanwhile, the gate electrode of the driving transistor T1 may also be connected to the third transistor T3 so that the data voltage DATA applied to the first electrode of the driving transistor T1 may be transmitted to the gate electrode of the driving transistor T1 through the third transistor T3. Meanwhile, the gate electrode of the driving transistor T1 is also connected to the fourth transistor T4 and may be initialized by receiving the first initialization voltage Vinit.

The second transistor T2 is a p-type transistor and has a silicon semiconductor as a semiconductor layer. The second transistor T2 is a transistor that receives the data voltage DATA into the pixel. The gate electrode of the second transistor T2 is connected to the first scan line 151 and one electrode, sometimes referred to as a lower boost electrode, of the boost capacitor Cboost. The first electrode of the second transistor T2 is connected to the data line 171. The second electrode of the second transistor T2 is connected to the first electrode of the driving transistor T1. When the second transistor T2 is turned on by the negative voltage of the first scan signal GW transmitted through the first scan line 151, the data voltage DATA transmitted through the data line 171 is transmitted to the first electrode of the driving transistor T1 and the data voltage DATA is finally transmitted to the gate electrode of the driving transistor T1 and stored in the storage capacitor Cst.

The third transistor T3 is an n-type transistor and has an oxide semiconductor as a semiconductor layer. The third transistor T3 is electrically connected to the second electrode of the driving transistor T1 and the gate electrode of the driving transistor T1. As a result, it is a transistor that allows the data voltage DATA to be compensated by the threshold voltage of the driving transistor T1 and then stored in the second storage electrode of the storage capacitor Cst. The gate electrode of the third transistor T3 is connected to the second scan line 152, and the first electrode of the third transistor T3 is connected to the second electrode of the driving transistor T1. The second electrode of the third transistor T3 is connected to the second storage electrode of the storage capacitor Cst, the gate electrode of the driving transistor T1, and the other electrode of the boost capacitor Cboost, sometimes referred to as an upper boost electrode. The third transistor T3 is turned on by the positive voltage among the second scan signal GC transmitted through the second scan line 152 to connect the gate electrode of the driving transistor T1 and the second electrode of the driving transistor T1 and to transmit the voltage applied to the gate electrode of the driving transistor T1 to the second storage electrode of the storage capacitor Cst to be stored to the storage capacitor Cst. At this time, the voltage stored in the storage capacitor Cst is stored in a state in which the voltage of the gate electrode of the driving transistor T1 when the driving transistor T1 is turned off is stored, and then the voltage of the threshold voltage Vth of the driving transistor T1 is compensated.

The fourth transistor T4 is an n-type transistor and has an oxide semiconductor as a semiconductor layer. The fourth transistor T4 initializes the gate electrode of the driving transistor T1 and the second storage electrode of the storage capacitor Cst. The gate electrode of the fourth transistor T4 is connected to the initialization control line 153, and the first electrode of the fourth transistor T4 is connected to the first initialization voltage line 127. The second electrode of the fourth transistor T4 is connected to the second electrode of the third transistor T3, the second storage electrode of the storage capacitor Cst, the gate electrode of the driving transistor T1, and the upper boost electrode of the boost capacitor Cboost. The fourth transistor T4 is turned on by the positive voltage of the initialization control signal GI received through the initialization control line 153, and at this time, the first initialization voltage Vinit is transmitted to the gate electrode of the driving transistor T1, the second storage electrode of the storage capacitor Cst, and the upper boost electrode of the boost capacitor Cboost to be initialized.

The fifth transistor T5 and the sixth transistor T6 are p-type transistors, and have a silicon semiconductor as a semiconductor layer.

The fifth transistor T5 serves to transfer the driving voltage ELVDD to the driving transistor T1. The gate electrode of the fifth transistor T5 is connected to the light emitting control line 155, the first electrode of the fifth transistor T5 is connected to the driving voltage line 172, and the second electrode of the fifth transistor T5 is connected to the first electrode of the driving transistor T1.

The sixth transistor T6 serves to transfer the light emitting current output from the driving transistor T1 to the light emitting diode LED. The gate electrode of the sixth transistor T6 is connected to the light emitting control line 155, the first electrode of the sixth transistor T6 is connected to the second electrode of the driving transistor T1, and the second electrode of the sixth transistor T6 is connected to the anode of the light emitting diode LED.

The seventh transistor T7 is a p-type or n-type transistor, and the semiconductor layer has a silicon semiconductor or an oxide semiconductor. The seventh transistor T7 serves for initializing the anode of the light emitting diode LED. The gate electrode of the seventh transistor T7 is connected to the first scan line 151, the first electrode of the seventh transistor T7 is connected to the anode of the light emitting diode LED, and the second electrode of the seventh transistor T7 is connected to the second initialization voltage line 128. When the seventh transistor T7 is turned on by the negative voltage of the first scan line 151, the second initialization voltage AVinit is applied to the anode of the light emitting diode LED to be initialized. On the other hand, the gate electrode of the seventh transistor T7 may be connected to a separate bypass control line and may be controlled by the first scan line 151 and separate wiring. In addition, according to an embodiment, the second initialization voltage line 128 to which the second initialization voltage AVinit is applied may be the same as the first initialization voltage line 127 to which the first initialization voltage Vinit is applied.

It is described that one pixel PX includes the seven transistors T1 to T7, two capacitors, e.g., the storage capacitor Cst and the boost capacitor Cboost. However, according to an embodiment, the boost capacitor Cboost may be omitted. Also, even if an embodiment in which the third transistor and the fourth transistor are formed of an n-type transistor, only one of them may be formed as an n-type transistor or the other transistor, e.g., the seventh transistor T7, may be formed as an n-type transistor.

In the above, the pixel positioned in the first display area DA1, e.g., the normal display area, the circuit structure of the pixel circuit unit for the second/first display area formed in the second/first display area DA2-1, e.g., the intermediate display area, and the light-emitting element positioned in the second/first display area DA2-1, e.g., the intermediate display area, have been described through FIG. 15.

Hereinafter, the cross-sectional structure of the pixel positioned in the first display area DA1, e.g., the normal display area, having the circuit structure of FIG. 15 and the pixel for the second/first display area formed in the second/first display area DA2-1, e.g., the intermediate display area, are described through FIG. 16. FIG. 16 also additionally shows the structure positioned on the light-emitting element of the anode Anode1, a middle layer, e.g., an EL layer, and a cathode Cathode according to an embodiment. Also, FIG. 16 shows the cross-sectional structure of two transistors, e.g., a LTPS TFT and an oxide TFT, the LTPS TFT may be one cross-sectional structure of the driving transistor T1, the second transistor T2, the fifth transistor T5, the sixth transistor T6, and the seventh transistor T7, and the oxide TFT may be one cross-sectional structure of the third transistor T3 and the fourth transistor T4.

The substrate 110 is a flexible substrate, and may have a structure in which a plurality of insulating layers are formed, and a structure in which a layer including plastic or polyimide and an inorganic insulating layer are repeatedly formed. According to an embodiment, the substrate 110 may be formed of a glass material.

A first metal layer BML1 is positioned on the substrate 110, and the first metal layer BML1 is covered by the buffer layer 111. According to an embodiment, the first metal layer BML1 may not be positioned in the first display area DA1, and may be positioned only in the second/first display area DA2-1. The buffer layer 111 may include an inorganic insulating material such as a silicon nitride (SiNx), a silicon oxide (SiOx), a silicon oxynitride (SiOxNy), etc.

A first semiconductor layer ACT1 formed of a silicon semiconductor, e.g., a polycrystalline semiconductor, is positioned on the buffer layer 111. The first semiconductor layer ACT1 includes channels of the driving transistor T1, the second transistor T2, the fifth transistor T5, the sixth transistor T6, and the seventh transistor T7, and has regions having a conductive layer characteristic by plasma processing or doping on both sides of each channel, thus functioning as a first electrode and a second electrode. The first metal layer BML1 may have a structure overlapping the channel of at least one transistor, e.g., the driving transistor T1, in a plan view among the driving transistor T1, the second transistor T2, the fifth transistor T5, the sixth transistor T6, and the seventh transistor T7.

A first gate insulating layer 141 may be positioned on the first semiconductor layer. The first gate insulating layer 141 may include an inorganic insulating material such as a silicon nitride (SiNx), a silicon oxide (SiOx), or a silicon oxynitride (SiOxNy).

A first gate conductive layer including a gate electrode GAT1 of the driving transistor T1 may be positioned on the first gate insulating layer 141. The first gate conductive layer may include each gate electrode of the second transistor T2, the fifth transistor T5, the sixth transistor T6, and the seventh transistor T7 as well as the driving transistor T1 and a lower boost electrode of the boost capacitor Cboost. The channel of each transistor may have a structure overlapping the gate electrode of each transistor on a plane. The first gate conductive layer may further include a first scan line 151 and a light emitting signal line 155. The first scan line 151 and the light emitting signal line 155 may extend in an approximately horizontal direction, e.g., the first direction. The first scan line 151 may be connected to the gate electrode of the second transistor T2. The first scan line 151 may be formed integrally with the gate electrode of the second transistor T2. The first scan line 151 is also connected to the gate electrode of the seventh transistor T7, and the gate electrode of the fifth transistor T5 and the gate electrode of the sixth transistor T6 are connected to the light emitting signal line 155.

After the first gate conductive layer including the gate electrode of the driving transistor T1 is formed, and a plasma treatment or a doping process is performed to make the exposed region of the first semiconductor layer conductive. That is, the first semiconductor layer covered by the first gate conductive layer is not conductive, and the portion of the first semiconductor layer not covered by the first gate conductive layer may have the same characteristic as the conductive layer. As a result, a transistor including the conductive portion has a p-type transistor characteristic, and the driving transistor T1, the second transistor T2, the fifth transistor T5, the sixth transistor T6, and the seventh transistor T7 may be p-type transistors.

A second gate insulating layer 142 may be positioned on the first gate conductive layer including the gate electrode of the driving transistor T1 and the first gate insulating layer 141. The second gate insulating layer 142 may include an inorganic insulating material such as a silicon nitride (SiNx), a silicon oxide (SiOx), or a silicon oxynitride (SiOxNy).

On the second gate insulating layer 142, a second gate conductive layer including a storage capacitor electrode CstE of the storage capacitor Cst, a second metal layer BML2 of the third transistor T3, and the second metal layer BML2 including a lower shielding layer of the fourth transistor T4 may be positioned. The second metal layer BML2 may be positioned under the channels of the third transistor T3 and the fourth transistor T4, respectively, and may serve to shield from optical or electromagnetic interference provided to the channel from the lower side.

The storage capacitor electrode CstE of the storage capacitor Cst overlaps the gate electrode GAT1 of the driving transistor T1 to form the storage capacitor Cst. The second metal layer BML2 of the third transistor T3 may overlap the channel and a gate electrode GAT2 of the third transistor T3, and the lower shielding layer of the fourth transistor T4 may overlap the channel and the gate electrode of the fourth transistor T4.

A first interlayer insulating layer 161 may be positioned on the second gate conductive layer. The first interlayer insulating layer 161 may include an inorganic insulating material such as a silicon nitride (SiNx), a silicon oxide (SiOx), or a silicon oxynitride (SiOxNy), and the inorganic insulating material may be formed thick according to an embodiment.

On the first interlayer insulating layer 161, a second semiconductor layer ACT2 including a channel, a first region, and a second region of the third transistor T3 and the fourth transistor T4 may be positioned. The channel, the first region, and the second region of the third transistor T3, and the channel, the first region, and the second region of the fourth transistor T4 may be connected to each other and formed integrally.

A third gate insulating layer 143 is positioned on the second semiconductor layer ACT2. The third gate insulating layer 143 may include an inorganic insulating material such as a silicon nitride (SiNx), a silicon oxide (SiOx), or a silicon oxynitride (SiOxNy).

On the third gate insulating layer 143, a third gate conductive layer including the gate electrode GAT2 of the third transistor T3 and the gate electrode of the fourth transistor T4 may be positioned. The gate electrode GAT2 of the third transistor T3 may overlap the channel of the third transistor T3, and may also overlap the second metal layer BML2 of the third transistor T3.

The third gate conductive layer may further include a second scan line 152, and the second scan line 152 may extend in an approximately horizontal direction, e.g., the first direction, and may be connected to the gate electrode GAT2 of the third transistor T3. The gate electrode GAT2 of the third transistor T3 may be electrically connected to the second metal layer BML2 of the third transistor T3 through the opening.

After forming the third gate conductive layer, through the plasma treatment or the doping process, the part of the oxide semiconductor layer covered by the third gate conductive layer is formed as a channel, and the part of the oxide semiconductor layer not covered by the third gate conductive layer is a conductor. The channel of the third transistor T3 may overlap the gate electrode GAT2, and the first region and the second region of the third transistor T3 may not overlap the gate electrode GAT2.

A second interlayer insulating layer 162 may be positioned on the third gate conductive layer. The second interlayer insulating layer 162 may have a single-layered or multi-layered structure. The second interlayer insulating layer 162 may include an inorganic insulating material such as a silicon nitride (SiNx), a silicon oxide (SiOx), or a silicon oxynitride (SiOxNy).

A first data conductive layer including various connection electrodes SD1 may be positioned on the second interlayer insulating layer 162. The various connection electrodes SD1 may be connected to the first semiconductor layer ACT1 or the second semiconductor layer ACT2, and some connection electrodes may constitute a second connection part CLr-2 so that the output current is transmitted to the anode Anode1.

A first organic layer 180 may be positioned on the first data conductive layer. The first organic layer 180 may include at least one organic material selected from the group consisting of polyimide, polyamide, acryl resin, benzocyclobutene, and phenol resin.

A second data conductive layer including a data line 171 and a driving voltage line 172 may be positioned on the first organic layer 180. The data line 171 and the driving voltage line 172 may extend approximately in a vertical direction, e.g., a second direction. The data line 171 may be connected to the second transistor T2. The driving voltage line 172 may be connected to the fifth transistor T5. Also, the driving voltage line 172 may be connected to the storage capacitor electrode CstE.

Referring to FIG. 16, the second data conductive layer may include a connection part CLr. The connection part CLr is connected to the second connection part CLr-2 through an opening formed in the first organic layer 180, and is finally connected to the sixth transistor T6 to receive the output current.

A second organic layer 181 and a third organic layer 182 may be positioned on the second data conductive layer including the data line 171, the driving voltage line 172, and the connection part CLr. The second organic layer 181 and the third organic layer 182 may include at least one organic material selected from the group consisting of polyimide, polyamide, acryl resin, benzocyclobutene, and phenol resin.

The anode Anode1 is positioned on the third organic layer 182. The anode Anode1 is electrically connected to the connection part CLr by an opening positioned in the second organic layer 181 and the third organic layer 182. The anode Anode1 may be composed of a single layer including a transparent conductive oxide film and a metal material or a multilayer including these. The transparent conductive oxide layer may include Indium Tin Oxide (ITO), poly-ITO, Indium Zinc Oxide (IZO), Indium Gallium Zinc Oxide (IGZO), and Indium Tin Zinc Oxide (ITZO), and the metal material may include silver (Ag), molybdenum (Mo), copper (Cu), gold (Au), and aluminum (Al).

A partition wall 380 covering at least part of the anode Anode1 while exposing the anode Anode1 may be positioned on the anode Anode1. The partition wall 380 is also referred to as a pixel defining layer (PDL) and may be formed of a black PDL having a black color. Referring to FIG. 16, a spacer 385 is positioned on the partition wall 380. The partition wall 380 and the spacer 385 may include a light blocking material or an organic material having a black color, and may also include a resin or a paste including carbon black, carbon nanotubes, or a black dye, metal particles, for example, nickel, aluminum, molybdenum, and alloys thereof, metal oxide particles, e.g., chromium nitride, and the like. In addition, the partition wall 380 and the spacer 385 may have a characteristic that light is not reflected and is absorbed/blocked, and may be formed of a negative type of organic material. The spacer 385 may be formed using one mask with the same material as the partition wall 380. That is, for the partition wall 380 and the spacer 385, through the process shown in FIG. 5 and FIG. 6, when forming the first light blocking part 385-2 and the second light blocking part 380-2 in the second/second display area DA2-2, the partition wall 380 and the spacer 385 may be formed together in the first display area DA1, e.g., the normal display area, and the second/first display area DA2-1, e.g., the intermediate display area. At this time, the partition wall 380 may be formed in the portion corresponding to the half-tone region HT among the used masks, and the spacer 385 may be formed in the portion corresponding to the light-transmitting region FT.

The middle layer EL layer and the cathode Cathode may be sequentially formed on the anode Anode1, the spacer 385, and the partition wall 380. The middle layer EL layer and the cathode Cathode may be formed over the entire region. The middle layer EL layer may include a functional layer and an emission layer, and the functional layer may be formed over the entire region, but the emission layer may be positioned only on the exposed anode Anode1 within the opening of the partition wall 380. The functional layer of the middle layer EL layer may include auxiliary layers such as an electron injection layer, an electron transport layer, a hole transport layer, and a hole injection layer. The hole injection layer and the hole transport layer may be positioned under the emission layer, and the electron transport layer and the electron injection layer may be positioned on the emission layer. According to an embodiment, the functional layer of the middle layer EL layer may also be formed in the second/second display area DA2-2 and the light transmission area LTA.

The cathode Cathode may be formed as a light-transmitting electrode or a reflecting electrode. According to an embodiment, the cathode Cathode may be a transparent or a semi-transparent electrode, and may be formed of a metal thin film having a small work function including lithium (Li), calcium (Ca), lithium fluoride/calcium (LiF/Ca), lithium fluoride/aluminum (LiF/Al), aluminum (Al), silver (Ag), magnesium (Mg), and a compound thereof. In addition, on the metal thin film, a transparent oxide conductive layer, e.g., a transparent conductive oxide, such as ITO (Indium Tin Oxide), IZO (Indium Zinc Oxide), zinc oxide (ZnO), or indium oxide (In₂O₃) may be further disposed. The cathode Cathode may be formed over the entire region, but may not be formed in the second/second display area DA2-2 and the light transmission area LTA according to embodiments. In addition, the cathode Cathode may have a semi-transparent characteristic, and in this case, a micro-cavity may be formed together with the anode. According to the micro-cavity structure, light of a specific wavelength is emitted upward by the spacing and characteristics between both electrodes, and as a result, may be displayed in red, green, or blue.

An encapsulation layer 400 is positioned on the cathode Cathode. The encapsulation layer 400 may include at least one inorganic layer and at least one organic layer, and according to an embodiment, may have a triple-layer structure including a first inorganic encapsulation layer, an organic encapsulation layer, and a second inorganic encapsulation layer. The encapsulation layer 400 may be for protecting the emission layer from moisture or oxygen that may be inflowed from the outside. According to an embodiment, the encapsulation layer 400 may include a structure in which an inorganic layer and an organic layer are sequentially further stacked.

In the embodiment of FIG. 16, a sensing insulating layer 510, a plurality of sensing electrodes 540 and 541, and an inorganic passivation layer 501 are positioned on the encapsulation layer 400 for touch sensing. In the embodiment of FIG. 16, a touch may be sensed in a capacitive type using two sensing electrodes 540 and 541.

Specifically, an inorganic passivation layer 501 is formed on the encapsulation layer 400, and a plurality of sensing electrodes 540 and 541 are formed on the inorganic passivation layer 501. A plurality of sensing electrodes 540 and 541 may be insulated with the sensing insulating layer 510 interposed between the sensing electrodes 540 and 541, and some of them may be electrically connected to each other through an opening positioned on the sensing insulating layer 510. Here, the sensing electrodes 540 and 541 may include a metal or a metal alloy such as aluminum (Al), copper (Cu), silver (Ag), gold (Au), molybdenum (Mo), titanium (Ti), or tantalum (Ta) and may be composed of a single layer or multiple layers.

The sensing electrodes 540 and 541 may be formed in the first display area DA1 and the second/first display area DA2-1, but may not be formed in the second/second display area DA2-2. Meanwhile, the inorganic passivation layer 501 and the sensing insulating layer 510 may be formed not only in the first display area DA1 and the second/first display area DA2-1, but also in the second/second display area DA2-2. In this case, both the inorganic passivation layer 501 and the sensing insulating layer 510 may be an inorganic insulating layer.

A light blocking member 220 and a color filter layer 230 are positioned on the overlying sensing electrode 541. The light blocking member 220 and the color filter layer 230 may be formed in the first display area DA1 and the second/first display area DA2-1, but are not formed in the second/second display area DA2-2.

The light blocking member 220 may be positioned so as to overlap the sensing electrodes 540 and 541 on a plane, and may be positioned so as to not overlap the anode Anode1 on a plane. This is to prevent the anode Anode1 capable of displaying an image from being covered by the light blocking member 220 and the sensing electrodes 540 and 541.

The color filter layer 230 may be positioned on the sensing insulating layer 510 and the light blocking member 220. The color filter layer 230 includes a red color filter that transmits red light, a green color filter that transmits green light, and a blue color filter that transmits blue light. Each color filter 230 may be positioned so as to overlap the anode Anode1 of the light-emitting element on a plane. The light emitted from the middle layer EL layer may be emitted as it passes through the color filter and is changed to a corresponding color.

The light blocking member 220 may be positioned between the color filters 230, respectively. According to an embodiment, the color filter layer 230 may be replaced with a color conversion layer, or a color conversion layer may be further included. The color conversion layer may include quantum dots.

A flattening layer covering the color filter layer 230 may be positioned on the color filter layer 230, and a polarizer may be additionally attached on the flattening layer.

In the above, the cross-sectional structure of the pixel circuit unit positioned in the first display area DA1, e.g., the normal display area, and the pixel circuit unit for the second/first display area formed in the second/first display area DA2-1, e.g., the intermediate display area, has been described according to the structure of FIG. 16.

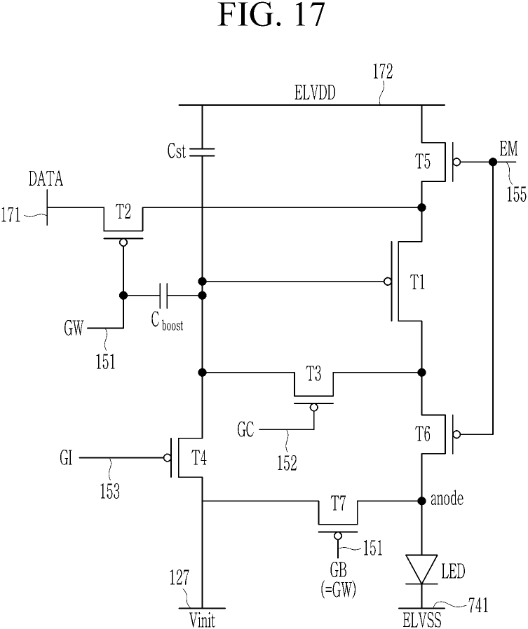

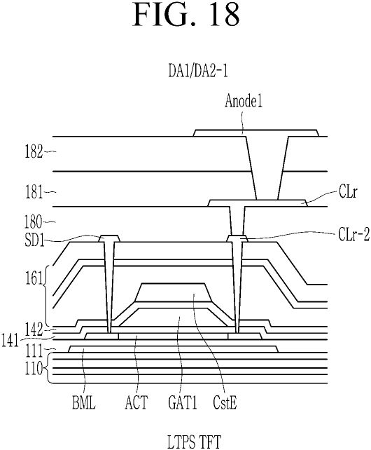

Hereinafter, the structure of the pixel circuit unit positioned in the first display area DA1, e.g., the normal display area, and the pixel positioned in the second/first display area DA2-1, e.g., the intermediate display area, is described through an embodiment of FIG. 17 and FIG. 18, and all the transistors positioned in the pixel use the same semiconductor layer.

FIG. 17 is a circuit diagram of one pixel included in a light emitting display device according to an embodiment. FIG. 18 is a view showing a cross-section of a pixel according to an embodiment of FIG. 17.

FIG. 17, unlike FIG. 15., is an embodiment in which the third transistor T3 and the fourth transistor T4 are formed of transistors including polycrystalline semiconductors, and thus all thin film transistors are formed of only polycrystalline semiconductors.

According to FIG. 17, one pixel PX includes a pixel circuit unit including a plurality of transistors and a capacitor and a light-emitting element LED receiving the current from the pixel circuit unit to be emitted.

As shown in FIG. 17, one pixel PX of the display device according to an embodiment includes a plurality of transistors T1, T2, T3, T4, T5, T6, and T7, a storage capacitor Cst, a boost capacitor C_{boost}, and a light-emitting element LED, which are connected to several wirings 127, 151, 152, 153, 154, 155, 171, 172, and 741.

A plurality of wirings 127, 151, 152, 153, 155, 171, 172, and 741 are connected to one pixel PX. A plurality of wirings include a first initialization voltage line 127, a first scan line 151, a second scan line 152, an initialization control line 153, a light emitting signal line 155, a data line 171, a driving voltage line 172, and a common voltage line 741.

The second scan line 152 and the initialization control line 153, which are different from FIG. 15, are described as follows.

The second scan line 152 may be the same wiring as the first scan line 151, and transmits a second scan signal GC, which is the same scan signal as the first scan signal GW, to the third transistor T3. The initialization control line 153 transmits an initialization control signal GI to the fourth transistor T4.

A plurality of transistors included in the pixel circuit unit may include a driving transistor T1, a second transistor T2, a third transistor T3, a fourth transistor T4, a fifth transistor T5, a sixth transistor T6, and a seventh transistor T7. A plurality of transistors may include a polycrystalline silicon semiconductor.

The third transistor T3 and the fourth transistor T4 that are different from FIG. 15 are described as follows.

The third transistor T3 is a p-type transistor and has a polycrystalline semiconductor as a semiconductor layer. The third transistor T3 electrically connects the second electrode of the driving transistor T1 and the gate electrode of the driving transistor T1. As a result, it is a transistor that allows the data voltage DATA to be compensated by the threshold voltage of the driving transistor T1 and then stored in the second storage electrode of the storage capacitor Cst. The gate electrode of the third transistor T3 is connected to the second scan line 152, and the first electrode of the third transistor T3 is connected to the second electrode of the driving transistor T1. The second electrode of the third transistor T3 is connected to the second storage electrode of the storage capacitor Cst, the gate electrode of the driving transistor T1 and the other electrode, sometimes referred to as an upper boost electrode, of the boost capacitor Cboost. The third transistor T3 is turned on by the negative voltage of the second scan signal GC received through the second scan line 152, so that the gate electrode of the driving transistor T1 and the second electrode of the driving transistor T1 are connected, and the voltage applied to the gate electrode of the driving transistor T1 is transmitted to the second storage electrode of the storage capacitor Cst to be stored in the storage capacitor Cst. At this time, the voltage stored in the storage capacitor Cst is stored in a state in which the voltage of the gate electrode of the driving transistor T1 when the driving transistor T1 is turned off is stored so that a threshold voltage Vth of the driving transistor T1 is compensated.

The fourth transistor T4 is a p-type transistor and has a polycrystalline semiconductor as a semiconductor layer. The fourth transistor T4 initializes the gate electrode of the driving transistor T1 and the second storage electrode of the storage capacitor Cst. The gate electrode of the fourth transistor T4 is connected to the initialization control line 153, and the first electrode of the fourth transistor T4 is connected to the first initialization voltage line 127. The second electrode of the fourth transistor T4 is connected to the second electrode of the third transistor T3, the second storage electrode of the storage capacitor Cst, the gate electrode of the driving transistor T1, and the upper boost electrode of the boost capacitor C_{boost}. The fourth transistor T4 is turned on by the negative voltage of the initialization control signal GI received through the initialization control line 153, and at this time, the first initialization voltage Vinit is transmitted to the gate electrode of the driving transistor T1, the second storage electrode of the storage capacitor Cst, and the upper boost electrode of the boost capacitor Cboost to be initialized.

Hereinafter, the cross-sectional structure of the first display area DA1 and the second/first display area DA2-1 is described with reference to FIG. 18.

The substrate 110 is a flexible substrate, and may have a structure in which a plurality of insulating layers are formed and a structure in which a layer including plastic or polyimide and an inorganic insulating layer are repeatedly formed. According to an embodiment, the substrate 110 may be formed of a glass material. Therefore, the substrate 110 may have various degrees of flexibility. The substrate 110 may be a rigid substrate or a flexible substrate capable of bending, folding, rolling, etc.

A metal layer BML is positioned on the substrate 110, and the metal layer BML is covered by the buffer layer 111. According to the embodiment, the metal layer BML may not be positioned in the first display area DA1, and may be positioned only in the second/first display area DA2-1. The buffer layer 111 blocks the transfer of impurities from the substrate 110 to the upper layer of the buffer layer 111, particularly the semiconductor layer ACT, thus preventing characteristic degradation of the semiconductor layer ACT and reducing stress. The buffer layer 111 may include an inorganic insulating material such as a silicon nitride (SiNx), a silicon oxide (SiOx), or a silicon oxynitride (SiOxNy).

The semiconductor layer ACT is positioned on the buffer layer 111. The semiconductor layer ACT may include polycrystalline silicon, and the semiconductor layer ACT includes a channel region overlapping a gate electrode GAT1, and first and second regions positioned on respective sides of the channel region. In the semiconductor layer ACT, the first and second regions except the channel region are doped with an impurity to have the same/similar conduction characteristics as the conductor.

A first gate insulating layer 141 is positioned on the semiconductor layer ACT. The first gate insulating layer 141 may include an inorganic insulating material such as a silicon nitride (SiNx), a silicon oxide (SiOx), and a silicon oxynitride (SiOxNy), and may have a single-layered or multi-layered structure.

On the first gate insulating layer 141, a first gate conductive layer including the gate electrode GAT1 is positioned. The gate electrode GAT1 may overlap the channel region of the semiconductor layer ACT on a plane.

A second gate insulating layer 142 is positioned on the first gate conductive layer. The second gate insulating layer 142 may include an inorganic insulating material such as a silicon nitride (SiNx), a silicon oxide (SiOx), and a silicon oxynitride (SiOxNy), and may have a single-layered or multi-layered structure.

On the second gate insulating layer 142, a second gate conductive layer including a storage capacitor electrode CstE is positioned. The storage capacitor electrode CstE overlaps the gate electrode GAT1 to constitute the storage capacitor Cst.

A first interlayer insulating layer 161 is positioned on the second gate conductive layer. The first interlayer insulating layer 161 may include an inorganic insulating material such as a silicon nitride (SiNx), a silicon oxide (SiOx), and a silicon oxynitride (SiOxNy), and may have a single-layered or multi-layered structure as shown in FIG. 18 which shows a structure composed of a plurality of layers.

A first data conductive layer including a connecting member SD1 connected to the semiconductor layer ACT is positioned on the first interlayer insulating layer 161. The connecting member SD1 may be electrically connected to the first region and the second region of the semiconductor layer ACT through openings formed in the first interlayer insulating layer 161, the second gate insulating layer 142, and the first gate insulating layer 141, respectively. One of the connecting members SD1 may configure the second connection part CLr-2 so that the output current is transferred to the anode Anode1.

A first organic layer 180 is positioned on the first data conductive layer, and the first organic layer 180 may include at least one organic material selected from a group consisting of polyimide, polyamide, acryl resin, benzocyclobutene, and phenol resin.

On the first organic layer 180, a second data conductive layer including a connection part CLr is positioned. The connection part CLr serves to connect the second connection part CLr-2 and the anode Anode1.

On the second data conductive layer, a second organic layer 181 and a third organic layer 182 are sequentially positioned, and the second organic layer 181 and the third organic layer 182 may include at least one organic material selected from a group consisting of polyimide, polyamide, acryl resin, benzocyclobutene, and phenol resin.

The anode Anode1 is positioned on the third organic layer 182, and the anode Anode1 constitutes one electrode of the light-emitting element. Although the structure above the anode Anode1 is not shown, the same or similar stacked structure to that of FIG. 16 may be formed.

Although FIG. 18 shows only one transistor, actually each pixel may include a plurality of transistors as shown in FIG. 17.

While this disclosure has been described in connection with what is presently considered to be practical embodiments, it is to be understood that the inventive concept is not limited to the disclosed embodiments. On the contrary, it is intended to cover various modifications and equivalent structuring included within the spirit and scope of the appended claims.

Description of symbols

| | |
|---|---|
| DP: display panel DA2-1: second/first display area | DA1: first display area DA2-2: second/second display area |
| EDr1, EDg1, EDb1: light-emitting element for first display area EDr2-1, EDg2-1, EDb2-1: light-emitting element for second/first display area EDr2-2, EDg2-2, EDb2-2: light-emitting element for second/second display area PCr1, PCg1, PCb1: pixel circuit unit for first display area PCr2-1, PCg2-1, PCb2-1: pixel circuit unit for second/first display area PCr2-2, PCg2-2, PCb2-2: pixel circuit unit for second/second display area Anode, Anode1, Anode2-2, Anode2-2r, Anode2-2g, Anode2-2b: anode 380-2, 380-2r, 380-2g, 380-2b, 385-2, 385-2r, 385-2g, 385-2b: light blocking part | |
| OP-path: opening OS: optical element | LTA: light transmission area |
| TCLr, TCLg, TCLb: transparent connection wiring | |
| CLr, CLg, CLb, CLr-2: connection part MASK: mask HT: transflective region 380: partition wall Cathode: cathode 110: substrate | 3800: material for light blocking part FT: light-transmitting region NT: light blocking region 385: spacer ILs: a plurality of inorganic layers 111: buffer layer |
| 141, 142, 143: gate insulating layer | |
| 161, 162: first interlayer insulating layer | |
| 180, 181, 182: organic layer | 185: upper organic layer |
| 220: light blocking member | 230: color filter |
| 400: encapsulation layer | |
| ACT, ACT1, ACT2: semiconductor layer | |
| BML, BML1, BML2: metal layer | |
| CstE: storage capacitor electrode | |

What is claimed is:

1. A light emitting display device comprising
a transparent display area including a light transmission area and a normal display area,
wherein the transparent display area includes:
an anode including an opening;
a first light blocking part filling the opening; and
a second light blocking part positioned along an exterior side of the anode, and
a height of a highest part of the first light blocking part is different than a height of a highest part of the second light blocking part.

2. The light emitting display device of claim 1, wherein
the first light blocking part and the second light blocking part include a light blocking material or a negative organic material having a black color.

3. The light emitting display device of claim 1, wherein
the height of the highest part of the first light blocking part is higher than the height of the highest part of the second light blocking part.

4. The light emitting display device of claim 3, wherein
the first light blocking part is divided into a periphery part and a center part, and a height of the center part is higher than a height of the periphery part.

5. The light emitting display device of claim 4, wherein
a partition wall and a spacer are positioned in the normal display area, and
the partition wall and the spacer comprise a same material as the first light blocking part and the second light blocking part.

6. The light emitting display device of claim 1, wherein
the height of the highest part of the first light blocking part is lower than the height of the highest part of the second light blocking part.

7. The light emitting display device of claim 6, wherein
a partition wall and a spacer are positioned in the normal display area, and
the partition wall and the spacer comprise a same material as the first light blocking part and the second light blocking part.

8. The light emitting display device of claim 1, wherein
among an entire area surrounded by the exterior side of the anode for the transparent display area, an area occupied by the opening is 5% or more and 20% or less.

9. The light emitting display device of claim 1, wherein
at least one of a plurality of insulating layers positioned in the normal display area and transparent connection wiring connected to the anode for the transparent display area are positioned in the light transmission area.

10. The light emitting display device of claim 9, wherein
the transparent connection wiring is connected to the anode for the transparent display area at a position where the first light blocking part and the second light blocking part, and the anode for the transparent display area, overlap on a plane.

11. The light emitting display device of claim 9, wherein
the transparent connection wiring is connected to the anode for the transparent display area at a position where the first light blocking part and the second light blocking part, and the anode for the transparent display area, do not overlap on a plane.

12. The light emitting display device of claim 11, wherein
a part where the transparent connection wiring and the anode for the transparent display area are connected overlaps the first light blocking part or the second light blocking part on a plane.

13. A light emitting display device comprising:
a normal display area where a pixel circuit unit for a normal display area and a light-emitting element for the normal display area connected to the pixel circuit unit for the normal display area are positioned;
a transparent display area where a light-emitting element for a light transmission area and the transparent display area is positioned; and
an intermediate display area where a pixel circuit unit for the intermediate display area, a light-emitting element for the intermediate display area connected to the pixel circuit unit for the intermediate display area, and a pixel circuit unit for the transparent display area connected to the light-emitting element for the transparent display area are positioned,
wherein the light-emitting element for the transparent display area includes an anode for the transparent display area, and
the anode for the transparent display area has an opening, and
the transparent display area further includes:
a first light blocking part filling the opening; and
a second light blocking part positioned along an exterior side of the anode, and
a height of a highest part of the first light blocking part is different than a height of a highest part of the second light blocking part.

14. The light emitting display device of claim 13, wherein
the height of the highest part of the first light blocking part is higher than the height of the highest part of the second light blocking part.

15. The light emitting display device of claim 14, wherein
the first light blocking part is divided into a periphery part and a center part, and a height of the center part is higher than a height of the periphery part.

16. The light emitting display device of claim 15, wherein
a partition wall and a spacer are positioned in the normal display area, and
the partition wall and the spacer comprise a same material as the first light blocking part and the second light blocking part.

17. The light emitting display device of claim 13, wherein
the height of the highest part of the first light blocking part is lower than the height of the highest part of the second light blocking part.

18. The light emitting display device of claim 17, wherein
a partition wall and a spacer are positioned in the normal display area, and
the partition wall and the spacer comprise a same material as the first light blocking part and the second light blocking part.

19. The light emitting display device of claim 13, wherein
an area occupied by the opening is 5% or more and 20% or less among an entire area surrounded by the exterior side of the anode for the transparent display area.

20. The light emitting display device of claim 13, wherein
in the light transmission area, at least one of a plurality of insulating layers positioned in the normal display area and transparent connection wiring connected to the anode for the transparent display area are positioned.
